(19) United States
(12) Patent Application Publication
(10) Pub. No.: US 2026/0112422 A1
(43) Pub. Date: Apr. 23, 2026

(54) ANALOG PROCESSING OF ACTIVATION FUNCTIONS

(71) Applicant: MICRON TECHNOLOGY, INC., BOISE, ID (US)

(72) Inventor: Michele Piccardi, Cupertino, CA (US)

(73) Assignee: MICRON TECHNOLOGY, INC., BOISE, ID (US)

(21) Appl. No.: 19/358,994

(22) Filed: Oct. 15, 2025

Related U.S. Application Data
(60) Provisional application No. 63/709,631, filed on Oct. 21, 2024.

(51) Int. Cl. G11C 16/26; G11C 16/04; G11C 16/30

(52) U.S. Cl. CPC G11C 16/26; G11C 16/0483; G11C 16/30

(57) ABSTRACT

Memories might include a controller configured to cause the memory to perform a sensing operation on a plurality of selected memory cells while their common source is connected to a first input of a transimpedance amplifier (TIA) and while a switch between the first input and an output of the TIA, and connected in parallel with an impedance of the TIA, is closed; sample a current level from the common source to the first input of the TIA; isolate the common source from the TIA; and supply the sampled current level to the first input of the TIA while the switch is open to develop an output voltage level on the output of the TIA representative of the sampled current level. The controller might further be configured to cause the memory to convert the output voltage level to a digital value representative of the sampled current level.

### RELATED APPLICATIONS

This application claims the benefit of U.S. Provisional Application No. 63/709,631, filed on Oct. 21, 2024, hereby incorporated herein in its entirety by reference.

### TECHNICAL FIELD

The present disclosure relates generally to integrated circuits and methods of their operation, and, in particular, in one or more embodiments, the present disclosure relates to memories configured to perform analog processing of activation functions for use in generating artificial intelligence (AI) computational patterns, e.g., including vector element multiplication.

### BACKGROUND

Integrated circuit devices traverse a broad range of electronic devices. One particular type includes memory devices, often referred to simply as memory. Memory devices are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage nodes (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array might be connected together to form an access line, such as a word line. Columns of the array include strings (often termed NAND strings) of memory cells connected together in series between a pair of select gates, e.g., a source select transistor and a drain select transistor. Each source select transistor might be connected to a common source, while each drain select transistor might be connected to a data line, such as column bit line. Variations using more than one select gate between a string of memory cells and the common source, and/or between the string of memory cells and the data line, are known.

An Artificial Neural Network (ANN) might use a network of neurons to process inputs to the network and to generate outputs from the network. In general, an ANN might be trained using supervised and/or unsupervised methods.

Deep learning might use multiple layers of machine learning to progressively extract features from input data, and might be implemented via ANNs, such as deep neural networks, deep belief networks, recurrent neural networks, and/or convolutional neural networks. Deep learning has been applied to many application fields, such as computer vision, speech/audio recognition, natural language processing, machine translation, bioinformatics, drug design, medical image processing, games, etc.

### BRIEF DESCRIPTION OF THE DRAWINGS

FIG. 1 is a simplified block diagram of a memory in communication with a processor as part of an electronic system, according to an embodiment.

FIGS. 2A-2C are schematics of a portion of an array of memory cells in accordance with an embodiment.

FIG. 3 details the computations of a Deep Learning Accelerator.

FIGS. 4A and 4B depict portions of an array of memory cells configured to store digits of a multiplicand in an analog fashion and a binary fashion, respectively, in accordance with embodiments.

FIG. 5 depicts a portion of an array of memory cells having a block of memory cells for use in discussing operations in accordance with embodiments.

FIG. 6A is an example of a Rectified Linear Unit (ReLU) activation function for use with embodiments.

FIG. 6B is an example of a Leaky ReLU activation function for use with embodiments.

FIG. 7 is a conceptual depiction of a Transimpedance Amplifier (TIA) in accordance with an embodiment and selectively connected to an Analog-to-Digital Converter (ADC).

FIG. 8A is a conceptual depiction of a TIA in accordance with an embodiment.

FIG. 8B is a conceptual depiction of an output voltage level response as a function of time for the TIA of FIG. 8A.

FIG. 8C is a conceptual depiction of current levels as a function of time to and from the TIA of FIG. 8A.

FIG. 9A is a conceptual depiction of a TIA in accordance with a further embodiment.

FIG. 9B is a conceptual depiction of an output voltage level response as a function of current for the TIA of FIG. 9A.

FIG. 10A is a conceptual depiction of a TIA in accordance with a still further embodiment.

FIG. 10B is a conceptual depiction of an output voltage level response as a function of current for the TIA of FIG. 10A.

FIGS. 11A-11D are block schematics of current mirrors that could be used with embodiments.

FIG. 12 is a block schematic of a TIA in accordance with an embodiment.

FIG. 13 is a flowchart of a method of operating a memory in accordance with an embodiment.

FIG. 14 is a flowchart of a method of operating a memory in accordance with a further embodiment.

FIG. 15 is a flowchart of a method of operating a memory in accordance with another embodiment.

FIG. 16 is a flowchart of a method of operating a memory in accordance with a further embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by a conductive path unless otherwise apparent from the context.

As used herein, multiple acts being performed concurrently will mean that each of these acts is performed for a respective time period, and each of these respective time periods overlaps, in part or in whole, with each of the remaining respective time periods. In other words, portions of each of those acts are simultaneously performed for at least some period of time.

Unless otherwise defined, directional references such as upper, top, lower, bottom, side, left, right, parallel, orthogonal, etc. used in the description of the figures refers to such directions relative to the orientation of the figure itself.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

An Artificial Neural Network (ANN) might use a network of neurons to process inputs to the network and to generate outputs from the network. For example, each neuron in the network might receive a set of inputs. Some of the inputs to a neuron might be the outputs of certain neurons in the network; and some of the inputs to a neuron might be the inputs provided to the neural network. The input/output relations among the neurons in the network represent the neuron connectivity in the network.

Each neuron might have a bias, an activation function, and a set of synaptic weights for its inputs respectively. The activation function might be in the form of a step function, a linear function, a log-sigmoid function, a Rectified Linear Unit (ReLU) function, etc. Different neurons in the network might have different activation functions.

Each neuron might generate a weighted sum of its inputs and its bias and then produce an output that is the function of the weighted sum, computed using the activation function of the neuron.

The relations between the input(s) and the output(s) of an ANN in general might be defined by an ANN model that includes the data representing the connectivity of the neurons in the network, as well as the bias, activation function, and synaptic weights of each neuron. Based on a given ANN model, a computing device can be configured to compute the output(s) of the network from a given set of inputs to the network. For example, the inputs to an ANN might be generated based on camera inputs; and the outputs from the ANN might be the identification of an item, such as an event or an object.

In general, an ANN might be trained using a supervised method where the parameters in the ANN are adjusted to minimize or reduce the error between known outputs associated with or resulted from respective inputs and computed outputs generated via applying the inputs to the ANN. Examples of supervised learning/training methods include reinforcement learning and learning with error correction.

Alternatively, or in combination, an ANN might be trained using an unsupervised method where the exact outputs resulted from a given set of inputs is not known before the completion of the training. The ANN can be trained to classify an item into a plurality of categories, or data points into clusters. Multiple training algorithms can be employed for a sophisticated machine learning/training paradigm.

Deep learning might use multiple layers of machine learning to progressively extract features from input data. For example, lower layers can be configured to identify edges in an image; and higher layers can be configured to identify, based on the edges detected using the lower layers, items captured in the image, such as faces, objects, events, etc. Deep learning can be implemented via ANNs, such as deep neural networks, deep belief networks, recurrent neural networks, and/or convolutional neural networks.

Deep learning has been applied to many application fields, such as computer vision, speech/audio recognition, natural language processing, machine translation, bioinformatics, drug design, medical image processing, games, etc.

The granularity of a Deep Learning Accelerator (DLA) operating on vectors and matrices corresponds to the largest unit of vectors/matrices that can be operated upon during the execution of one instruction by the DLA. During the execution of the instruction for a predefined operation on vector/matrix operands, elements of vector/matrix operands can be operated upon by the DLA in parallel to reduce execution time and/or energy consumption associated with memory/data access. The operations on vector/matrix operands of the granularity of the DLA can be used as building blocks to implement computations on vectors/matrices of larger sizes.

The implementation of a typical/practical ANN involves vector/matrix operands having sizes that are larger than the operation granularity of the DLA. To implement such an ANN using the DLA, computations involving the vector/matrix operands of large sizes can be broken down to the computations of vector/matrix operands of the granularity of the DLA. The DLA can be programmed via instructions to carry out the computations involving large vector/matrix operands. For example, atomic computation capabilities of the DLA in manipulating vectors and matrices of the granularity of the DLA in response to instructions can be programmed to implement computations in an ANN.

In some implementations, the DLA might lack some of the logic operation capabilities of a typical Central Processing Unit (CPU). However, the DLA can be configured with sufficient logic units to process the input data provided to an ANN and generate the output of the ANN according to a set of instructions generated for the DLA. Thus, the DLA can perform the computation of an ANN with little or no help from a CPU or another processor. Optionally, a conventional general purpose processor can also be configured as part of the DLA to perform operations that cannot be implemented efficiently using the vector/matrix processing units of the DLA, and/or that cannot be performed by the vector/matrix processing units of the DLA.

A typical ANN can be described/specified in a standard format (e.g., Open Neural Network Exchange (ONNX)). A compiler can be used to convert the description of the ANN into a set of instructions for the DLA to perform calculations of the ANN. The compiler can optimize the set of instructions to improve the performance of the DLA in implementing the ANN.

The DLA can have local storage, such as registers, buffers and/or caches, configured to store vector/matrix operands and the results of vector/matrix operations. Intermediate results in the registers can be pipelined/shifted in the DLA as operands for subsequent vector/matrix operations to reduce time and energy consumption in accessing memory/data and thus speed up typical patterns of vector/matrix operations in implementing a typical ANN. The capacity of registers, buffers and/or caches in the DLA is typically insufficient to hold the entire data set for implementing the computation of a typical ANN. Thus, a random access memory coupled to the DLA might be configured to provide an improved data storage capability for implementing a typical ANN. For example, the DLA might load data and instructions from the random access memory and store results back into the random access memory.

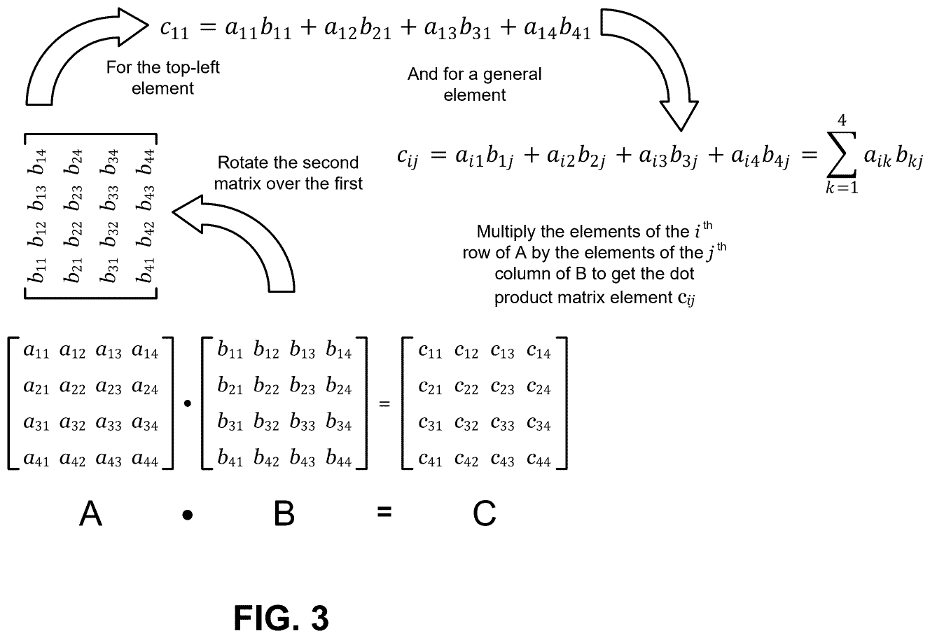

These computations can be replicated within a NAND memory as described in U.S. patent application Ser. No. 18/757,909 to Yudanov et al., filed Jun. 28, 2024, and titled VECTOR ELEMENT MULTIPLICATION IN NAND MEMORY. Specifically, an array of series-connected (e.g., NAND) memory cells can be configured to store data values representative of digits of elements of a multiplicand vector (e.g., a stored vector). A voltage level representative of a digit of an element of a multiplier vector (e.g., an input vector) might be applied to data lines connected to the memory cells storing the data values representative of the digits of element of the multiplicand vector and, with these memory cells connected to their respective data lines and a common source, a combined current through these strings of series-connected memory cells might be representative of a multiplication partial product of the element of the multiplicand vector and the digit of the element of the multiplier vector. By sequentially applying the remaining digits of the element of the multiplier vector in a similar manner, these multiplication partial products can be accumulated to generate the multiplication product of the element of the multiplicand vector and the element of the multiplier vector. These multiplication products can then be combined with other such multiplication products to generate a vector dot product of the multiplicand vector and the multiplier vector. And the vector dot products can be combined to generate a matrix dot product as will be described with reference to FIG. 3.

Application of the activation function to such multiplication results is typically performed in the digital domain, e.g., after the analog-to-digital conversion of the current representative of the multiplication partial product of an element of a multiplicand vector and a digit of an element of a multiplier vector. This typically involves the use of arithmetic-logic units at a cost of relatively advanced CMOS processing in fabrication, and relatively high power consumption during use.

Various embodiments described herein seek to facilitate the application of an activation function in the analog domain, prior to the analog-to-digital conversion of the current representative of a multiplication partial product of an element of a multiplicand vector and a digit of an element of a multiplier vector. Such application of the activation function might facilitate lower fabrication cost of the relevant circuitry and lower power consumption during use, relative to the use of arithmetic-logic units.

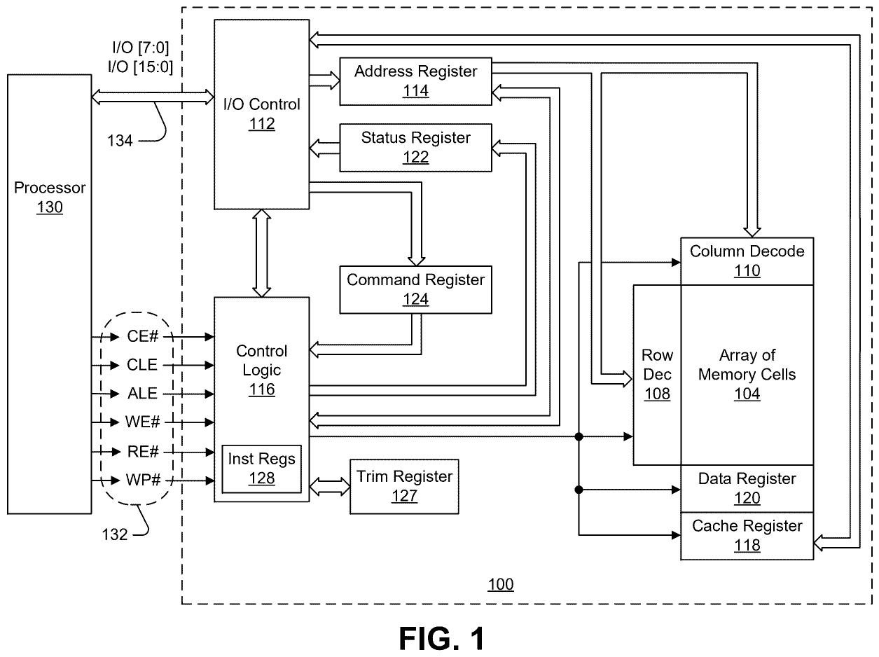

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two different data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands from the external processor 130 and might generate status information for the external processor 130, i.e., control logic 116 is configured to perform array operations (e.g., sensing operations [which might include read operations and verify operations], programming operations and/or erase operations) on the array of memory cells 104 in accordance with embodiments. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional or alternative circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

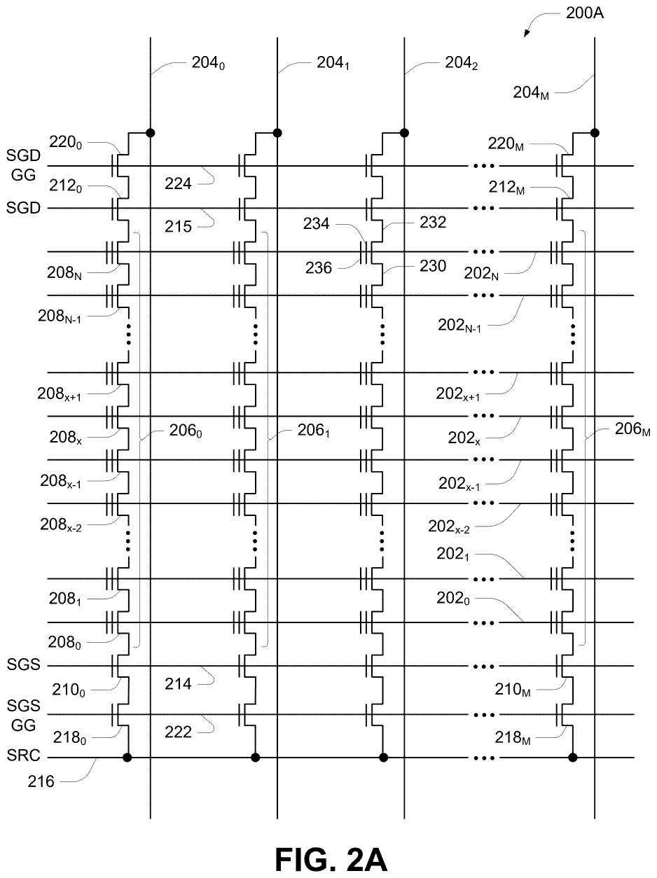

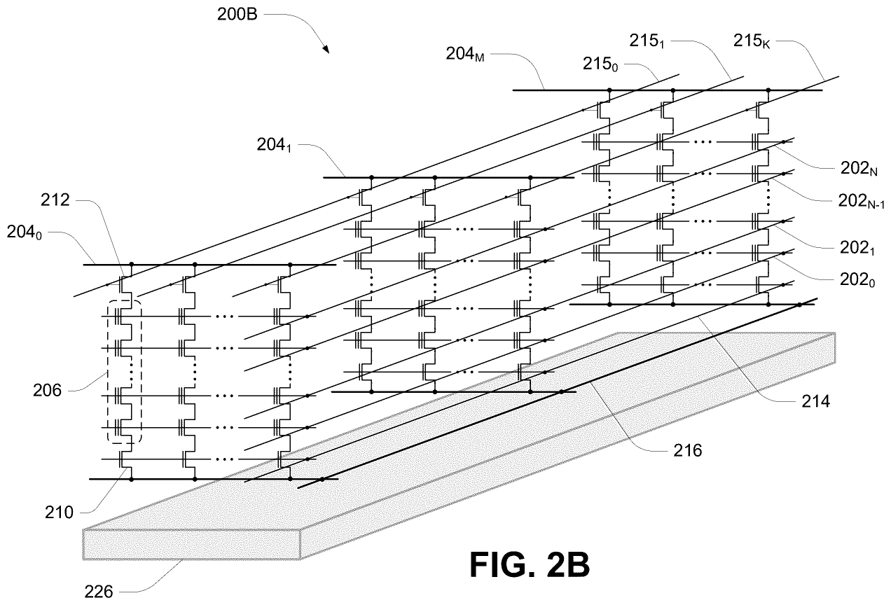

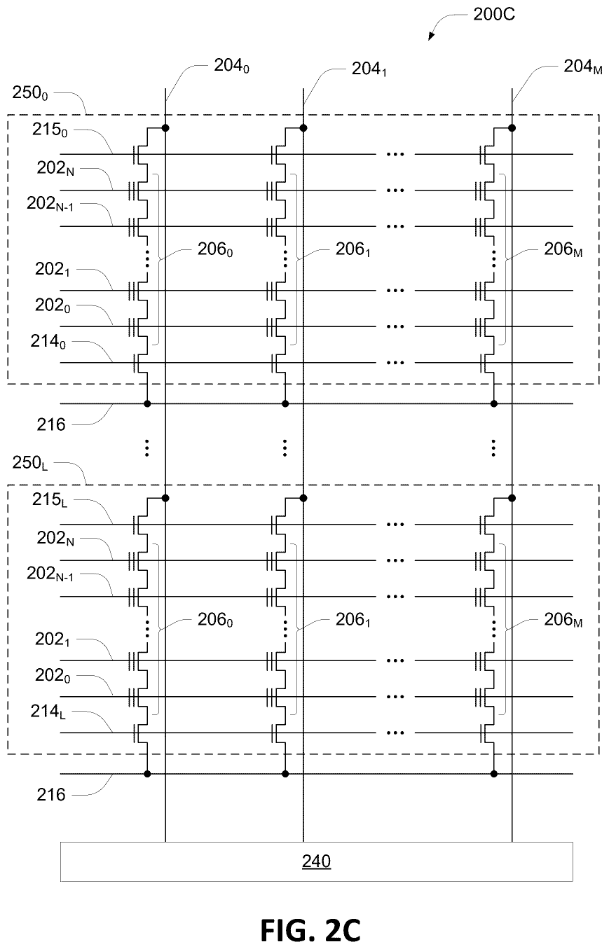

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines, such as access lines (e.g., word lines) 202₀ to 202_{N}, and data lines, such as data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. Some of the memory cells 208 might represent dummy memory cells, e.g., memory cells not intended to store user data. Dummy memory cells are typically not accessible to a user of the memory, and are typically incorporated into the NAND string 206 for operational advantages, as are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 2120 to 212M (e.g., that might be drain select transistors, commonly referred to as select gate drain). Select gates 210₀ to 210_{M} might be commonly connected to a select line 214, such as a source select line (SGS), and select gates 2120 to 212, might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. A control gate of each select gate 210 might be connected to select line 214. A control gate of each select gate 212 might be connected to select line 215.

The select gates 210 for each NAND string 206 might be connected in series between its memory cells 208 and a GIDL (gate-induced drain leakage) generator gate 218 (e.g., a field-effect transistor), such as one of the GIDL generator (GG) gates 218₀ to 218_{M}. The GG gates 218₀ to 218 might be referred to as source GG gates. The source GG gates 218₀ to 218_{M} might each be connected (e.g., directly connected) to the source 216, and selectively connected to their respective NAND strings 206₀ to 206_{M}. Alternatively, a source select gate 210 and its GG gate 218 might represent a single gate, e.g., connected (e.g., directly connected) to the source 216, and connected (e.g., directly connected) to a respective NAND string 206.

The select gates 212 of each NAND string 206 might be connected in series between its memory cells 208 and a GG gate 220 (e.g., a field-effect transistor), such as one of the GG gates 220₀ to 220_{M}. The GG gates 220₀ to 220_{M} might be referred to as drain GG gates. The drain GG gates 220₀ to 220_{M} might be connected (e.g., directly connected) to their respective data lines 204₀ to 204_{M}, and selectively connected to their respective NAND strings 206₀ to 206_{M}. Alternatively, a drain select gate 212 and its GG gate 220 might represent a single gate, e.g., connected (e.g., directly connected) to a respective data line 204, and connected (e.g., directly connected) to a respective NAND string 206.

GG gates 218₀ to 218_{M} might be commonly connected to a control line 222, such as an SGS_GG control line, and GG gates 220₀ to 220_{M} might be commonly connected to a control line 224, such as an SGD_GG control line. Although depicted as traditional field-effect transistors, the GG gates 218 and 220 might utilize a structure similar to (e.g., the same as) the memory cells 208. The GG gates 218 and 220 might represent a plurality of GG gates connected in series, with each GG gate in series configured to receive a same or independent control signal. In general, the GG gates 218 and 220 might have threshold voltages different than (e.g., lower than) the threshold voltages of the select gates 210 and 212, respectively. Threshold voltages of the source GG gates 218 might be different than (e.g., higher than) threshold voltages of the drain GG gates 220. Threshold voltages of the GG gates 218 and 220 might be of an opposite polarity than, and/or might be lower than, threshold voltages of the select gates 210 and 212, respectively. For example, the select gates 210 and 212 might have positive threshold voltages (e.g., 2V to 4V), while the GG gates 218 and 220 might have negative threshold voltages (e.g., −1V to −4V). The GG gates 218 and 220 might be provided to assist in the generation of GIDL current into a channel of their corresponding NAND string 206 during an erase operation, for example.

A source of each GG gate 218 might be connected to common source 216. The drain of each GG gate 218 might be connected to a select gate 210 of the corresponding NAND string 206. For example, the drain of GG gate 218₀ might be connected to the source of select gate 210₀ of the corresponding NAND string 206₀. Therefore, in cooperation, each select gate 210 and GG gate 218 for a corresponding NAND string 206 might be configured to selectively connect that NAND string 206 to common source 216. A control gate of each GG gate 218 might be connected to control line 222.

The drain of each GG gate 220 might be connected to the data line 204 for the corresponding NAND string 206. For example, the drain of GG gate 220₀ might be connected to the data line 204₀ for the corresponding NAND string 206₀. The source of each GG gate 220 might be connected to a select gate 212 of the corresponding NAND string 206. For example, the source of GG gate 220₀ might be connected to select gate 2120 of the corresponding NAND string 206₀. Therefore, in cooperation, each select gate 212 and GG gate 220 for a corresponding NAND string 206 might be configured to selectively connect that NAND string 206 to the corresponding data line 204. A control gate of each GG gate 220 might be connected to control line 224.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. For clarity, the GG gates and their control lines are not depicted in FIG. 2B.

The three-dimensional NAND memory array 200B might incorporate vertical structures which might include conductively-doped semiconductor pillars, which might be solid or hollow, around which memory cells of NAND strings 206 might be formed. A portion of a pillar might act as a body or channel (e.g., channel region) of the memory cells of NAND strings 206, e.g., a region through which current might flow when a memory cell, e.g., a field-effect transistor, is activated. Each of the NAND strings 206 might be selectively connected to a data line 204₀-204_{N} through a select gate 212 and to a common source 216 through a select gate 210. Multiple NAND strings 206 might be selectively connected to the same data line 204. Subsets of NAND strings 206 can be connected to their respective data lines 204 by biasing the select lines 215₀-215_{K} to selectively activate particular select gates 212 each between a NAND string 206 and a data line 204. The select gates 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation generally remains as a matter of convenience.

FIG. 2C is a further schematic of a portion of an array of memory cells 200C as could be used in a memory of the type described with reference to FIG. 1, e.g., as a portion of array of memory cells 104. Like numbered elements in FIG. 2C correspond to the description as provided with respect to FIG. 2A. Array of memory cells 200C might include strings of series-connected memory cells (e.g., NAND strings) 206, access (e.g., word) lines 202, data (e.g., bit) lines 204, select lines 214 (e.g., source select lines), select lines 215 (e.g., drain select lines) and common source 216 as depicted in FIG. 2A. A portion of the array of memory cells 200A might be a portion of the array of memory cells 200C, for example. FIG. 2C depicts groupings of NAND strings 206 into blocks of memory cells 250, e.g., blocks of memory cells 250₀-250_{L} . . . . Blocks of memory cells 250 might be groupings of memory cells 208 that might be erased together in a single erase operation, sometimes referred to as erase blocks. Each block of memory cells 250 might represent those NAND strings 206 commonly associated with a single select line 215, e.g., select line 215₀. The source 216 for the block of memory cells 250₀ might be a same source as the source 216 for the block of memory cells 250_{L}. For example, each block of memory cells 250₀-250_{L} might be commonly selectively connected to the source 216. Access lines 202 and select lines 214 and 215 of one block of memory cells 250 might have no direct connection to access lines 202 and select lines 214 and 215, respectively, of any other block of memory cells of the blocks of memory cells 250₀-250_{L}. Alternatively, the source 216 for the block of memory cells 250₀ might be isolated from the source 216 for the block of memory cells 250_{L}

The data lines 204₀-204_{M} might be connected (e.g., selectively connected) to a buffer portion 240, which might be a portion of a data buffer of the memory. The buffer portion 240 might correspond to a memory plane (e.g., the set of blocks of memory cells 250₀-250_{L}). The buffer portion 240 might include sense circuits (not shown in FIG. 2C) for sensing data values indicated on respective data lines 204.

FIG. 3 details some computations supporting a deep learning accelerator (DLA). Consider the example of the matrix A as a multiplicand and the matrix B as a multiplier. The dot product of these two matrices A and B to produce the results matrix C would include the dot product of the first row (e.g., vector) of the matrix A (e.g., a₁₁, a₁₂, a₁₃, and a₁₄) and the first column (e.g., vector) of the matrix B (e.g., b₁₁, b₂₁, b₃₁, and b₄₁) to yield the element of the matrix C of its first row and first column (e.g., c₁₁) according to Equation 1:

$${c}_{11} = {a}_{11} {b}_{11} + {a}_{12} {b}_{21} + {a}_{13} {b}_{31} + {a}_{14} {b}_{41} \qquad Eq . 1$$

Remaining elements of the matrix C might be similarly determined for the various rows of the matrix A and the various columns of the matrix B in a similar matter. For example, for each value of i from 1 to 4, and each value of j from 1 to 4 for the matrices depicted in FIG. 3, the element cᵢⱼ of the matrix C can be determined from the general Equation 2:

$${c}_{ij} = {a}_{i 1} {b}_{1 j} + {a}_{i 2} {b}_{2 j} + {a}_{i 3} {b}_{3 j} + {a}_{i 4} {b}_{4 j} = {\sum }_{k = 1}^{4} {a}_{ik} {b}_{kj} \qquad Eq . 2$$

Each element of the multiplicand matrix A, the multiplier matrix B, and the results matrix C might represent a number, which might be binary or otherwise. As such, each element of the results matrix C might represent a summation or accumulation of the products of corresponding elements of a row from the multiplicand matrix A and a column of the multiplier matrix B.

As noted earlier, these computations can be performed using a NAND memory. For example, to multiply two numbers within a NAND memory, a set of memory cells commonly connected to a same access line, or collectively connected to a set of access lines, could be programmed to have threshold voltages indicative of one number, e.g., the multiplicand, while voltages could be applied to the data lines selectively connected to the set of memory cells that are indicative of individual digits (e.g., bits) of the other number, e.g., the multiplier. Note that the multiplicand might utilize either binary encoding or thermometric encoding for storage of its data, e.g., the value of 12 base 10 might be binary encoded as 1100, or thermometric encoded as 111111111111. While thermometric encoding might utilize more memory cells for storage, it might also afford higher accuracy than binary encoding.

Subsets of the set of memory cells might be programmed to represent a respective digit (binary or thermometric) of the multiplicand, e.g., by collectively presenting a respective resistance value between their respective data lines and the common source in response to a same control signal or set of control signals applied to their control gates. Each subset of memory cells might contain one or more memory cells (which could include all memory cells) of a single string of series-connected memory cells, or of multiple strings of series-connected memory cells. As will be described in more detail, a subset of memory cells corresponding to one digit of the multiplicand might contain a same number of memory cells and/or a same arrangement of memory cells as the subsets of memory cells for each remaining digit of the multiplicand. Alternatively, a subset of memory cells corresponding to one digit of the multiplicand might contain a different number of memory cells and/or a different arrangement of memory cells than a respective subset of memory cells for one or more remaining digits of the multiplicand. The set of memory cells might be programmed in a binary fashion, e.g., each memory cell either activated (e.g., to represent a first logic level) or deactivated (e.g., to represent a second logic level different than the first logic level) in response to its respective control signal, or in an analog fashion, e.g., different memory cells exhibiting different levels of resistance (e.g., R, R/2, R/4, R/8, etc.) in response to a same control signal or a same set of control signals.

Respective digits of the multiplier might be applied to the respective data lines of the set of memory cells sequentially while the set of memory cells receives its control signal or set of control signals. In this manner, the collective current level through the set of memory cells from its respective data lines to the common source might be indicative of the value of an element of the multiplicand vector multiplied by one digit of an element of the multiplier vector. The voltage levels corresponding to the digits of the multiplier vector might be applied in a binary fashion, e.g., applying a first voltage level to generate a first voltage differential between each data line and the common source (e.g., to represent a first logic level) and applying a second voltage level to generate a second voltage differential lower than the first voltage differential (e.g., a de minimis voltage differential) between each data line and the common source (e.g., to represent a second logic level different than the first logic level).

Alternatively, the voltage levels corresponding to the digits of the multiplier vector might be applied in an analog fashion. For example, to represent the first logic level (e.g., “1”) for a least significant digit (e.g., least significant bit or LSB), a first voltage level might be applied to its respective data line(s) to generate a first voltage differential between the respective data line(s) and the common source, to represent the first logic level for a next significant digit (e.g., a second digit), a second voltage level higher than the first voltage level (e.g., two times the first voltage level) might be applied to its respective data line(s) to generate a second voltage differential (e.g., two times the first voltage differential) between the respective data line(s) and the common source, to represent the first logic level for a next significant digit (e.g., a third digit), a third voltage level higher than the second voltage level (e.g., two times the second voltage level) might be applied to its respective data line(s) to generate a third voltage differential (e.g., two times the second voltage differential) between the respective data line(s) and the common source, and so on. Similarly, to represent the second logic level (e.g., “0”) for any digit, a voltage level might be applied to the data lines to generate a voltage differential lower than any voltage differential generated for the first logic level (e.g., a de minimis voltage differential) between each data line and the common source.

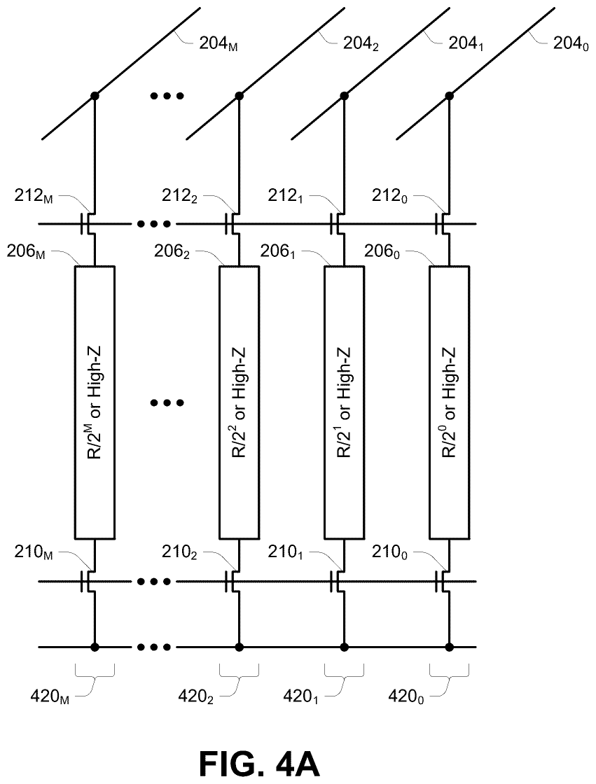

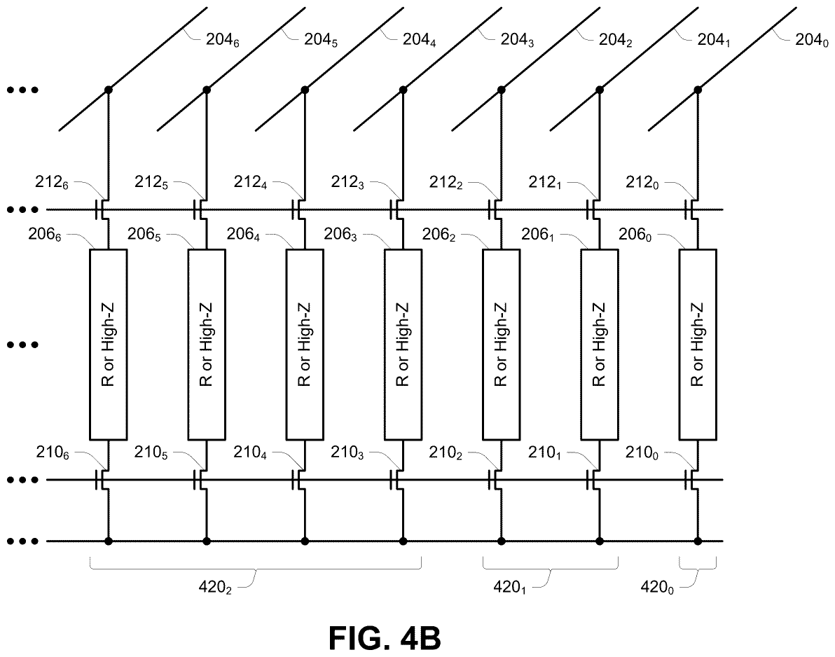

FIGS. 4A and 4B depict portions of an array of memory cells configured to store digits of a multiplicand in an analog fashion and a binary fashion, respectively. Like numbered elements in FIGS. 4A-4B correspond to the description as provided with respect to FIG. 2A. Note that the access lines 202 are not depicted in FIGS. 4A-4B for clarity.

In FIG. 4A, the subset of memory cells corresponding to a first digit 420₀ of the multiplicand, e.g., a least significant digit, might include one or more (e.g., which might include all memory cells) memory cells of the string of series-connected memory cells 206₀ that are configured either to exhibit a resistance value of R/2° or R to represent a first logic level (e.g., “1”) for the digit 420₀, or to exhibit a high impedance (High-Z) to represent a second logic level (e.g., “0”) different than the first logic level for the digit 420₀ in response to a set of control signals applied to the access lines 202 (not depicted in FIG. 4A) for the strings of series-connected memory cells 206. The subset of memory cells corresponding to a next digit 420₁ of the multiplicand might include one or more memory cells (e.g., which might include all memory cells) of the string of series-connected memory cells 206₁ that are configured either to exhibit a resistance value of R/2¹ or R/2 to represent the first logic level for the digit 420₁, or to exhibit a high impedance to represent the second logic level for the digit 420₁ in response to the set of control signals applied to the access lines 202 (not depicted in FIG. 4A) for the strings of series-connected memory cells 206. The subset of memory cells corresponding to a next digit 420₂ of the multiplicand might include one or more memory cells (e.g., which might include all memory cells) of the string of series-connected memory cells 206₂ that are configured either to exhibit a resistance value of R/2² or R/4 to represent the first logic level for the digit 420₂, or to exhibit a high impedance to represent the second logic level for the digit 420₂ in response to the set of control signals applied to the access lines 202 (not depicted in FIG. 4A) for the strings of series-connected memory cells 206. This might continue in like fashion for each additional digit 420 of the multiplicand up to a last digit 420_{M} of the multiplicand, e.g., a most significant digit, such that the subset of memory cells corresponding to the last digit 420_{M} of the multiplicand might include one or more memory cells (e.g., which might include all memory cells) of the string of series-connected memory cells 206_{N} that are configured either to exhibit a resistance value of R/2^{M} to represent the first logic level for the digit 420_{M}, or to exhibit a high impedance to represent the second logic level for the digit 420_{M} in response to the set of control signals applied to the access lines 202 (not depicted in FIG. 4A) for the strings of series-connected memory cells 206. In this manner, each string of series-connected memory cells 206 might correspond to a respective digit (e.g., a single respective digit) of the multiplicand, and each digit of the multiplicand might correspond to one or more strings of series-connected memory cells 206.

Note that although FIG. 4A depicts a single string of series-connected memory cells 206 as corresponding to each digit 420 of the multiplicand, each digit 420 of the multiplicand might correspond to one or more strings of series-connected memory cells 206. For example, the subset of memory cells corresponding to the first digit 420₀ of the multiplicand might include one or more memory cells of two strings of series-connected memory cells 206 that are each configured either to exhibit a resistance value of R to represent the first logic level for the digit 420₀ or to exhibit a high impedance to represent the second logic level for the digit 420₀, the subset of memory cells corresponding to the second digit 420₁ of the multiplicand might include one or more memory cells of two strings of series-connected memory cells 206 that are each configured either to exhibit a resistance value of R/2 to represent the first logic level for the digit 420₁ or to exhibit a high impedance to represent the second logic level for the digit 420₁, the subset of memory cells corresponding to the third digit 420₂ of the multiplicand might include one or more memory cells of two strings of series-connected memory cells 206 that are each configured either to exhibit a resistance value of R/4 to represent the first logic level for the digit 420₂ or to exhibit a high impedance to represent the second logic level for the digit 420₂, and so on. In addition, although the strings of series-connected memory cells 206 corresponding to each digit 420 of the multiplicand are depicted to be immediately adjacent one another, the strings of series-connected memory cells 206 corresponding to the digits 420 of the multiplicand might be interleaved with strings of series-connected memory cells 206 not corresponding to the digits 420 of the multiplicand, e.g., every other string of series-connected memory cells 206 or some other mixture of strings of series-connected memory cells 206 corresponding to the digits 420 of the multiplicand and strings of series-connected memory cells 206 not corresponding to the digits 420 of the multiplicand. Furthermore, while depicted to be arranged in an order from least significant digit 420₀ to most significant digit 420_{M}, their order could be altered or even randomized as this would not be expected to alter their collective conductance in any significant manner.

In FIG. 4B, the subset of memory cells corresponding to a first digit 420₀ of the multiplicand, e.g., a least significant digit, might include one or more memory cells (e.g., which might include all memory cells) of the string of series-connected memory cells 206₀ that are configured either to exhibit a resistance value of R to represent a first logic level (e.g., “1”) for the digit 420₀, or to exhibit a high impedance to represent a second logic level (e.g., “0”) different than the first logic level for the digit 420₀ in response to a set of control signals applied to the access lines 202 (not depicted in FIG. 4B) for the strings of series-connected memory cells 206. The subset of memory cells corresponding to a next digit 420₁ of the multiplicand might include one or more memory cells (e.g., which might include all memory cells) of the strings of series-connected memory cells 206₁ and 206₂ that are configured either to exhibit a resistance value of R for each string of series-connected memory cells 206 to represent the first logic level for the digit 420₁, or to exhibit a high impedance for each string of series-connected memory cells 206 to represent the second logic level for the digit 420₁ in response to the set of control signals applied to the access lines 202 (not depicted in FIG. 4B) for the strings of series-connected memory cells 206. The subset of memory cells corresponding to a next digit 420₂ of the multiplicand might include one or more memory cells (e.g., which might include all memory cells) of the strings of series-connected memory cells 2063 through 2066 that are configured either to exhibit a resistance value of R for each string of series-connected memory cells 206 to represent the first logic level for the digit 420₂, or to exhibit a high impedance for each string of series-connected memory cells 206 to represent the second logic level for the digit 420₂ in response to the set of control signals applied to the access lines 202 (not depicted in FIG. 4B) for the strings of series-connected memory cells 206. This might continue in like fashion for each additional digit 420 of the multiplicand up to a last digit of the multiplicand, e.g., a most significant digit, such that the subset of memory cells corresponding to each digit of the multiplicand might include one or more memory cells (e.g., which might include all memory cells) of a number of strings of series-connected memory cells 206 that might be two times the number of strings of series-connected memory cells 206 corresponding to a previous digit of the multiplicand, where each string of series-connected memory cells 206 corresponding to that digit of the multiplicand is configured either to exhibit a resistance value of R to represent the first logic level for that digit 420, or to exhibit a high impedance to represent the second logic level for that digit 420 in response to the set of control signals applied to the access lines 202 (not depicted in FIG. 4B) for the strings of series-connected memory cells 206.

As with the example of FIG. 4A, the first digit of the multiplicand 420₀ might correspond to more than one string of series-connected memory cells 206, with like adjustments to the number of strings of series-connected memory cells 206 for each remaining digit of the multiplicand. In addition, strings of series-connected memory cells 206 corresponding to the digits 420 of the multiplicand might be interleaved with strings of series-connected memory cells 206 not corresponding to the digits 420 of the multiplicand, and/or might be rearranged. Furthermore, FIG. 4B also might be used to describe thermometric encoding. For example, a set of memory cells being programmed to represent a number in thermometric encoding might include one or more memory cells (e.g., which might include all memory cells) of a number of strings of series-connected memory cells 206 that is a multiple (e.g., 1, 2, 3, etc.) of the number to be represented, e.g., to represent 3 base 10, the set of memory cells might include one or more memory cells of each of three strings of series-connected memory cells 206, e.g., strings of series-connected memory cells 206₀-206₂, each configured to exhibit a resistance value of R, with remaining strings of series-connected memory cells 206 corresponding to the multiplicand might be configured to exhibit a high impedance.

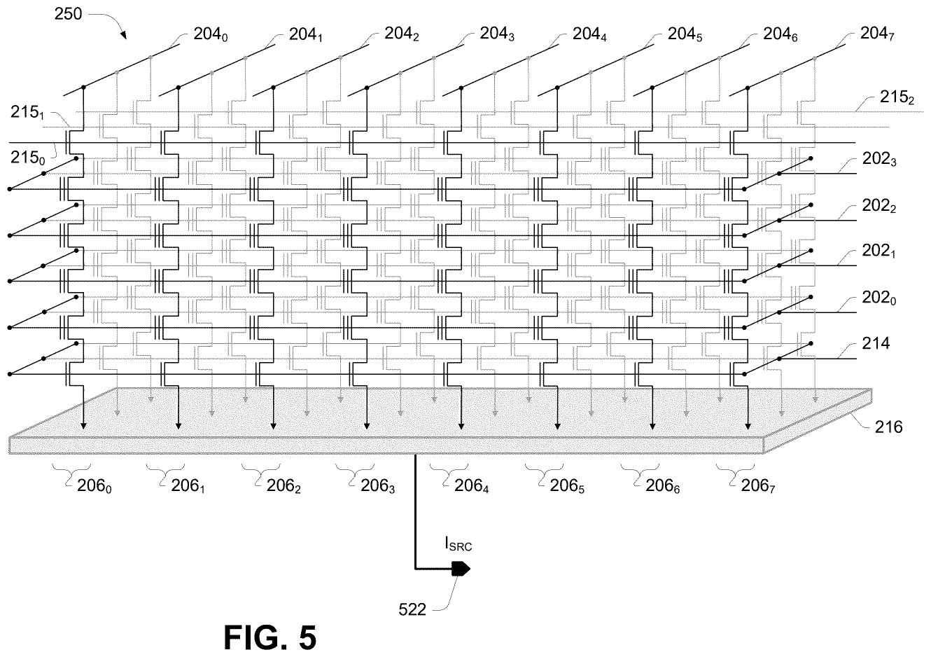

FIG. 5 depicts a portion of an array of memory cells (e.g., a block of memory cells 250) for use in discussing arithmetic operations in accordance with embodiments. FIG. 5 depicts eight strings of series-connected memory cells (e.g., 206₀-206₇) including memory cells (not labeled in FIG. 5) selectively connected to data lines 204₀-204₇ through select gates (not labeled in FIG. 5) responsive to a control signal applied to select line 215₀ and selectively connected to a common source 216 through select gates (not labeled in FIG. 5) responsive to a control signal applied to select line 214, eight strings of series-connected memory cells (not labeled in FIG. 5) including memory cells (not labeled in FIG. 5) selectively connected to data lines 204₀-204₇ through select gates (not labeled in FIG. 5) responsive to a control signal applied to select line 2151 and selectively connected to the common source 216 through select gates (not labeled in FIG. 5) responsive to a control signal applied to select line 214, and eight strings of series-connected memory cells (not labeled in FIG. 5) including memory cells (not labeled in FIG. 5) selectively connected to data lines 204₀-204₇ through select gates (not labeled in FIG. 5) responsive to a control signal applied to select line 215₂ and selectively connected to the common source 216 through select gates (not labeled in FIG. 5) responsive to a control signal applied to select line 214.

During a sensing operation, a sense voltage level might be applied to a selected access line, e.g., access line 202₃ of FIG. 5. The sense voltage level might be configured to activate memory cells connected to the selected access line storing a first data value and to deactivate memory cells connected to the selected access line storing a second data value. These memory cells might store weights of the multiplication partial product. Remaining unselected access lines, e.g., access lines 202₀-202₂, might receive a pass voltage level configured to activate memory cells connected to the unselected access lines regardless of their stored data values. All other transistors between the selected memory cells and the data lines 204 and between the selected memory cells and the common source 216 might also be activated. For example, in the example of FIG. 5, the select line 214 might receive a voltage level configured to activate the source select transistors, and one or more of the select lines 215₀-215₂ might receive a voltage level configured to activate the corresponding drain select transistors. Note that while in a traditional sensing operation, only one of the select lines 215₀-215₂ might receive a voltage level configured to activate its corresponding drain select transistors, because the sensing is occurring from the source side, more than one selected memory cell can be concurrently connected to its corresponding data line. Thus, various embodiments might connect one or more NAND strings 206 to an individual data line 204 during a sensing operation. This facilitates an increase in the number of memory cells available to represent an element of a multiplicand vector in a single sensing operation, e.g., increasing the number of available digits to represent the element. Similarly, only one of the access lines 202 might receive the sense voltage in a traditional sensing operation, but various embodiments might apply the sense voltage to more than one access line 202 during the sensing operation.

With the selected memory cells connected to their respective data lines 204 and to the common source 216, one or more of the data lines 204, e.g., one or more of the data lines 204₀-204₇, might receive a voltage level representative of a digit of an element of a multiplier vector. For example, in response to the value of the digit of the multiplier vector having a first input data value, the data lines 204 might receive a positive voltage level, and in response to the value of the digit of the multiplier vector having a second input data value, the data lines 204 might receive a reference potential, e.g., 0V, Vss, or ground, or a same voltage level as the common source 216. The resulting combined current flow through the selected memory cells to the common source 216 might represent a multiplication partial product of the weights and the digit of the multiplier vector. The node 522 might sink this current flow (e.g., I_{SRC}) from the common source 216 during the sensing operation.

Activation functions are utilized in determining the output of a neuron of an artificial neural network. One common activation function is the ReLU or Rectified Linear Unit activation function. An example of a ReLU activation function is provided by Equation 3:

$$f ( x ) = a * max ( 0 , x ) = a * ( x + \vert x \vert ) / 2 \qquad Eq . 3$$

ReLU activation functions have gained significant popularity for DLAs because they have been shown to facilitate supervised deep neural networks without requiring unsupervised pre-training, and are generally thought to provide faster training with large or complex data sets than sigmoid or other similar activation functions.

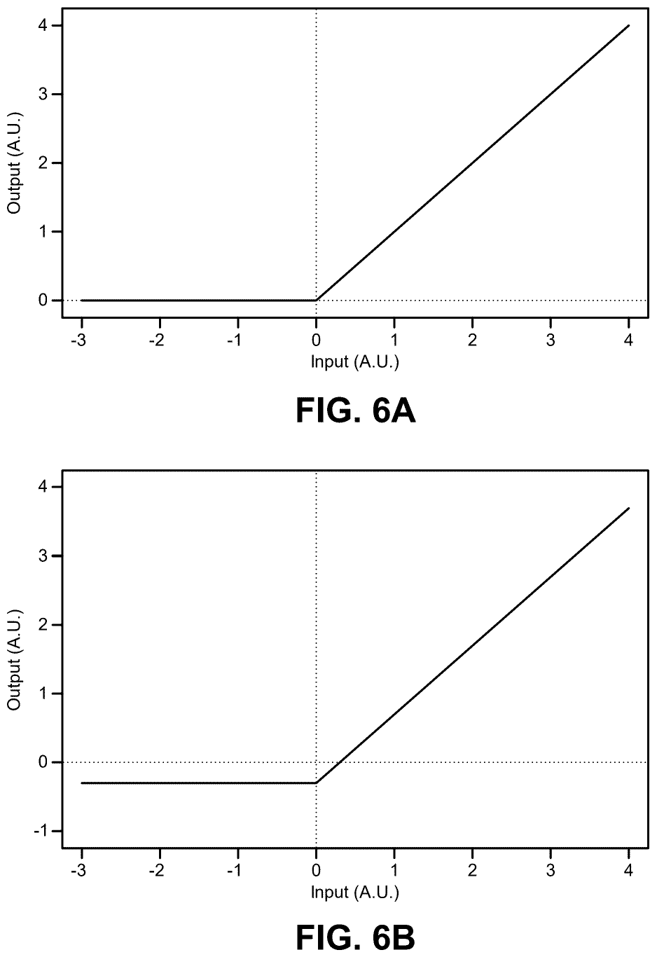

ReLU activation functions generally return a zero output for all non-positive inputs, and an increasing output for increasing values of positive inputs. A Leaky ReLU activation function is similar to ReLU but is capable of returning a negative output value, e.g., in response to negative inputs. Leaky ReLU might facilitate mitigation of vanishing gradients with ReLU and permit the definition of more generalized models. FIG. 6A is an example of a ReLU activation function, while FIG. 6B is an example of a Leaky ReLU activation function, which might alternatively be referred to as a Shifted ReLU activation function. In the examples of FIGS. 6A and 6B, the inputs and outputs might each be expressed in terms of arbitrary units (A.U.) of voltage, current, or some other metric.

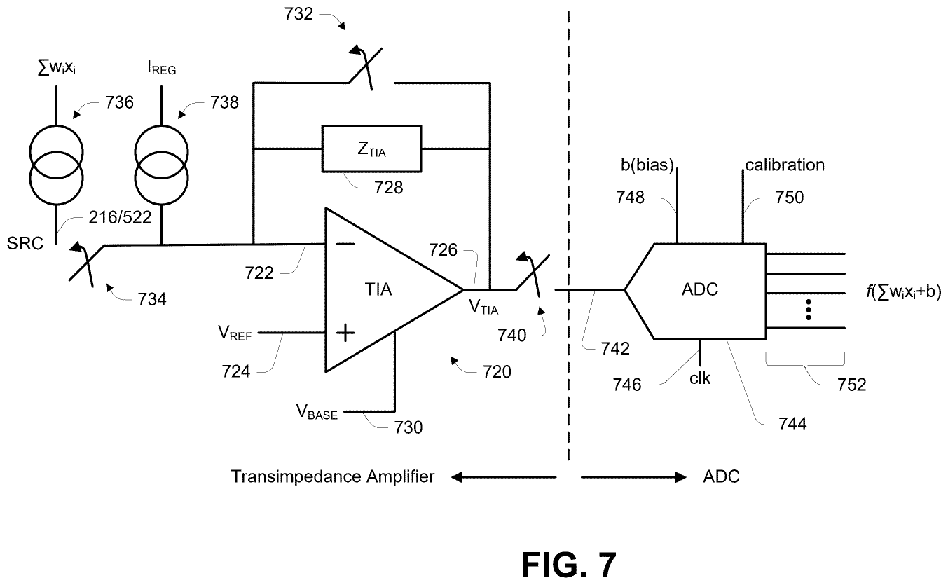

ReLU and/or Leaky ReLU activation functions as described herein might be implemented using a transimpedance amplifier (TIA) to convert the current representative of a multiplication partial product, e.g., from the common source 216, to a voltage level representative of the multiplication partial product with the applied activation function. FIG. 7 is a conceptual depiction of a TIA in accordance with an embodiment and selectively connected to an analog-to-digital converter (ADC).

In FIG. 7, the TIA 720 might have a first input 722, a second input 724, an output 726, and an impedance (Z_{TIA}) 728 connected between its first input 722 and its output 726. The first input 722 might be an inverted input, and the second input 724 might be a non-inverted input. The second input 724 might be configured to receive a voltage level V_{REF}, e.g., a reference voltage level. The TIA 720 might further include a voltage node 730 configured to receive a voltage level VBASE, a base voltage level. This might represent the lowest voltage level received by the TIA 720, e.g., providing a lowest value of its output voltage level.

The impedance 728 might represent a resistor, and might generally include one or more active or passive circuit elements configured to present a level of resistance (e.g., a predetermined level of resistance) to current flow from the first input 722 to the output 726, e.g., in excess of conductive lines between the input 722 and the output 726. In general, a TIA is configured as an operational amplifier (e.g., op-amp) with an impedance connected between its first input and its output. Although not depicted, a capacitance (e.g., a capacitor) might further be connected between the first input 722 and the output 726 in parallel with the impedance 728.

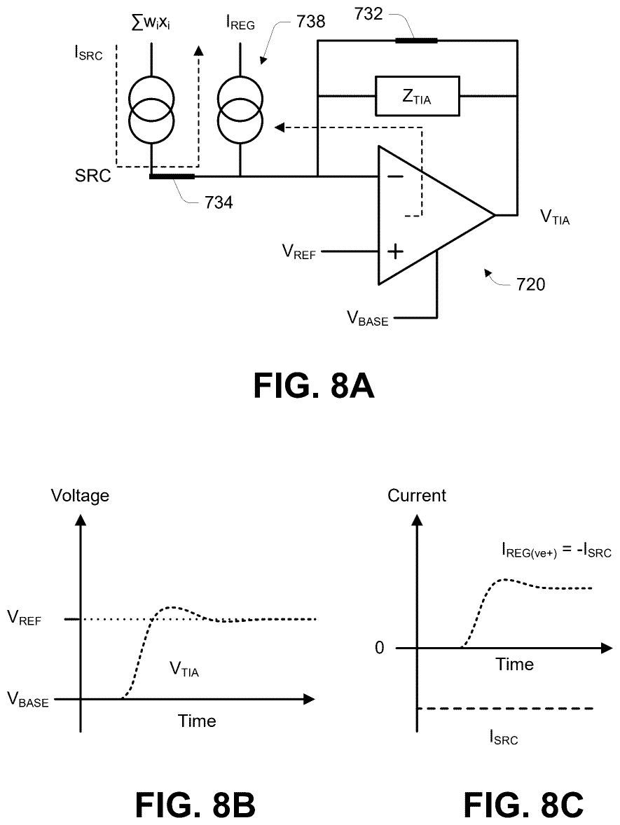

Unconventionally, for various embodiments, the TIA 720 might further include a switch 732 connected between the first input 722 and the output 726 in parallel with the impedance 728, e.g., to permit a direct connection between the input 722 and the output 726, bypassing the impedance 728. The switch 732 might represent a field-effect transistor (FET), which might be an n-type FET (e.g., nFET) or a p-type FET (e.g., pFET). The function of the bypass will be discussed with reference to FIG. 8A.

The first input 722 of the TIA 720 might be selectively connected to the node 522 and thus to the common source 216 through a switch 734 in order to receive a current from the node 522 representative of a multiplication partial product. This might be represented by Σwᵢxᵢ, where wᵢ might represent a weight, e.g., a value stored to one of the selected memory cells, and xᵢ might represent an input, e.g., a value applied to the corresponding data line for that selected memory cell. The switch 734 might represent a FET, which might be an nFET or a pFET. The current source 736 might represent the memory cells generating the current, such as discussed with reference to FIG. 5.

The current source 738 might represent circuitry for sampling a level of current from the TIA 720 for one portion of its operation, and for supplying the sampled current level to the TIA 720 for another portion of its operation. Although depicted as a single current source, the current source 738 might represent first circuitry for sampling the level of current level from the TIA 720 and second circuitry for supplying the sampled current level to the TIA 720 that are different from one another.

As used herein, sampling a current level might involve generating another current level proportional to (e.g., equal to) an original current level. The other current level proportional to the original current level might be referred to as a sampled current level. This might further involve sampling a control gate voltage level configured to pass a current level equal to the original current level through a first transistor, retaining that control gate voltage level, and using the retained control gate voltage level to generate the other current level proportional to (e.g., equal to) the original current level through a different transistor of a same type (e.g., n-type or p-type). Alternatively, this might further involve applying a first control gate voltage level configured to pass a current level equal to the original current level through a first transistor of a first type to a control gate of a different transistor of the first type, using current flow through the different transistor of the first type to generate a second control gate voltage level on a control gate of a first transistor of a second type, sampling the second control gate voltage level, retaining the second control gate voltage level, and using the retained second control gate voltage level to generate the other current level proportional to (e.g., equal to) the original current level through a different transistor of the second type.

The output 726 of the TIA 720 might be selectively connected to a first input 742 of an ADC 744 through a switch 740. The switch 740 might represent a FET, which might be an nFET or a pFET. The ADC 744 might be provided to convert the voltage level received from the output 726 of the TIA 720 to a digital value.

The ADC 744 might include a plurality of outputs 752, each configured to output a respective digital signal (e.g., logic high or logic low). Collectively, the plurality of outputs 752 might output a digital value representative of the voltage level of the output 726 of the TIA 720. The ADC 744 might further include a second input 746 for receiving a clock signal clk, which might be used to control the sampling rate of the analog signal received at its first input 742 for use in developing its output signals. The ADC 744 might further include a third input 748 for receiving a bias signal b, which might be used to add an analog offset b to the input prior to digital conversion or a digital offset to the digitally converted output. And the ADC 744 might further include a fourth input 750 configured to receive a calibration signal, which might be used to adjust its output signals, e.g., to adjust a value of the output signals produced in response to a received input voltage level to match (or more closely match) an expected value of the output signals. In this manner, the plurality of outputs 752 might provide a digital output vector that is indicative of the function ƒ(Σwᵢxᵢ+b).

Operation of the TIA 720 to produce a voltage level representative of Σwᵢxᵢ in accordance with embodiments might involve connecting its first input 722 to the node 522 to receive the current level I_{SRC} while bypassing the impedance 728, and sampling the resulting current level from the TIA 720, then isolating its first input 722 from the node 522, removing the bypass of the impedance 728, and providing the sampled current level to its first input 722. Further embodiments might then adjust the level of the voltage level V_{REF} to adjust the intercept of the activation function to a desired level, e.g., determined by the model. FIGS. 8A-10B provide additional details of such operation.

FIG. 8A is a conceptual depiction of a TIA 720 in accordance with an embodiment. During a sensing operation on a block of memory cells, the TIA 720 might initially be connected to the common source SRC by closing the switch 734. As used herein, a switch is closed if it is configured to facilitate current flow through the switch, e.g., such as an activated FET, and it is open if it is configured to inhibit or eliminate current flow through the switch, e.g., such as a deactivated FET. The switch 732 might also be closed to bypass the impedance Z_{TIA}, providing a direct connection between the input and the output of the TIA 720. In this configuration, the TIA 720 might seek to sink a current level (e.g., I_{REG}) from the TIA 720 equal to the current level I_{SRC} sourced from the common source SRC in order to produce a voltage level at its first (e.g., inverted) input and its output (e.g., V_{TIA}) equal to the voltage level at its second (e.g., non-inverted) input (e.g., V_{REF}). This current level I_{REG} might be sinked through current source 738, e.g., to the voltage level VBASE. This current level I_{REG} can then be sampled using any of a variety of known methods. For example, a current mirror could be used to replicate the current level.

FIG. 8B is a conceptual depiction of an output voltage level response as a function of time for the TIA 720 of FIG. 8A. As depicted in FIG. 8B, with the bypass of the impedance Z_{TIA}, the voltage level V_{TIA} at the output of the TIA 720 might be expected to initially increase then reach a steady-state voltage level equal to the voltage level V_{REF} received at the second input of the TIA 720. The voltage level V_{REF} at this stage might be chosen such that the expected current levels from the common source SRC might be expected to produce a linear or near-linear response to possible values of the multiplication partial products. The voltage level VBASE might be a reference potential, e.g., 0V, Vss or ground. Alternatively, VBASE might have a negative voltage level.

FIG. 8C is a conceptual depiction of current levels as a function of time to and from the TIA 720 of FIG. 8A. As depicted in FIG. 8C, with the bypass of the impedance Z_{TIA}, the current level I_{REG} might be expected to initially increase then reach a steady-state current level equal to an absolute value of the current level I_{SRC} (e.g., equal to −I_{SRC}).

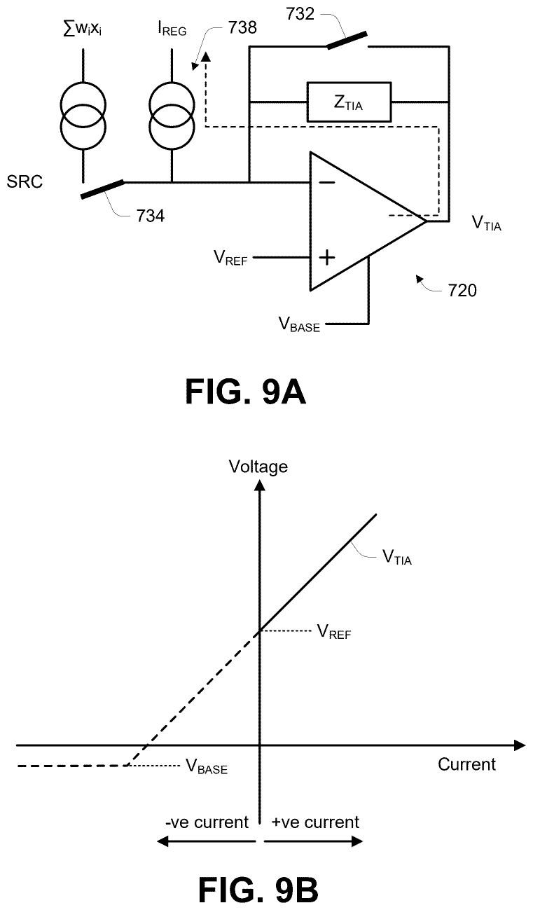

FIG. 9A is a conceptual depiction of a TIA 720 in accordance with a further embodiment. After sampling of the current level I_{REG}, the TIA 720 might be isolated from the common source SRC by opening the switch 734. This frees the block of memory cells to perform another access operation. The switch 732 might also be opened to permit current flow through the impedance Z_{TIA}, e.g., removing the direct connection between the input and output of the TIA 720. The sampled current level I_{REG} could be sourced to the first input of the TIA 720. In this manner, and in accordance with Ohm's law (e.g., V=Z*I), the resulting output voltage level V_{TIA} might be representative of the current level I_{REG}, and thus representative of the current level I_{SRC} and of the multiplication partial product value.

FIG. 9B is a conceptual depiction of an output voltage level response as a function of current for the TIA 720 of FIG. 9A. The ReLU function of FIG. 9B generated by the TIA 720 might have a Y-axis (voltage level) intercept at the voltage level V_{REF}. The ReLU function is shown in dashed line for current levels received at the first input of the TIA 720 that are negative as the sensing operation would not be expected to sink current from the inverted input of the TIA 720.

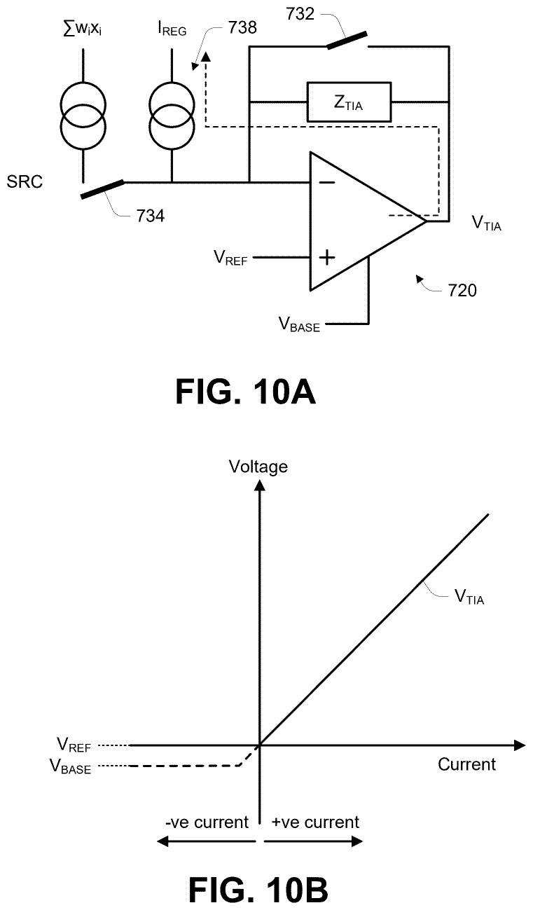

FIG. 10A is a conceptual depiction of a TIA 720 in accordance with a still further embodiment. While sourcing the sampled current level I_{REG} to the inverted input of the TIA 720, the voltage level of the voltage level V_{REF} might be changed to move the intercept of its voltage level response based on the preferences of the neural network. The voltage level of the voltage level VBASE might also be changed in view of the preference of the neural network. For example, if the preference of the neural network is to have a Leaky ReLU activation function providing a positive output in response to a positive input, and providing a negative output in response to a negative input, the voltage level V_{REF} might set to be 0V and the voltage level VBASE might be set to a negative voltage level. This response is depicted in FIG. 10B.

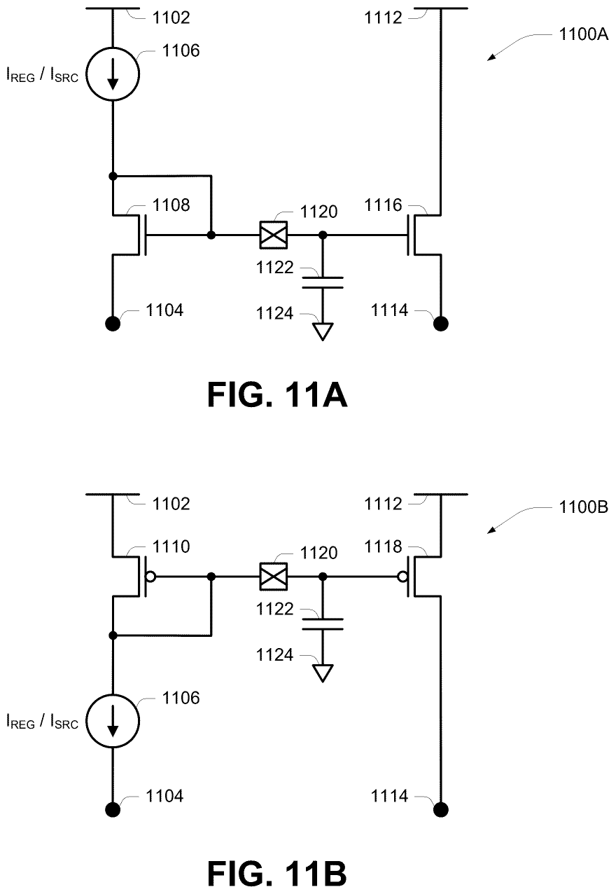

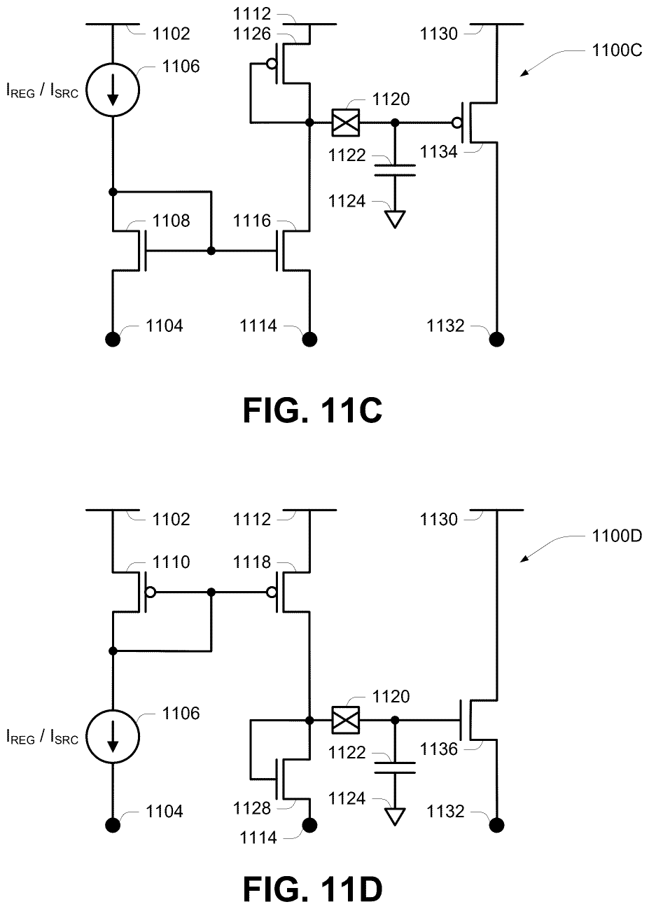

FIG. 11A is a block schematic of a current mirror 1100A using nFETs that could be used with embodiments. The current mirror 1100A might include a first voltage node 1102 configured to receive a first voltage level and a second voltage node 1104 configured to receive a second voltage level lower than the first voltage level. A current source 1106 connected between the first voltage node 1102 and the second voltage node 1104 might represent the current flow I_{SRC} from the block of memory cells being sensed or the current flow I_{REG} being absorbed to VBASE from the TIA 720, e.g., sinked from the TIA 720. A first nFET 1108 might be connected between the current source 1106 and the second voltage node 1104. The first nFET 1108 might be a diode-connected transistor with its drain connected to its control gate. Although depicted in FIG. 11A as a diode-connected nFET, the first nFET 1108 might simply represent a transistor passing a current level to be sampled, whether diode-connected or not.

The current mirror 1100A might further include a third voltage node 1112 configured to receive a third voltage level and a fourth voltage node 1114 configured to receive a fourth voltage level lower than the third voltage level. The third voltage level might be a same voltage level as the first voltage level, and the fourth voltage level might be a same voltage level as the second voltage level. A second nFET 1116 might be connected between the third voltage node 1112 and the fourth voltage node 1114. The second nFET 1116 might have the same size, e.g., a same width and length, as the first nFET 1108. A control gate of the second nFET 1116 might be selectively connected to the control gate of the first nFET 1108 through a switch 1120. The switch 1120 might be a FET, such as an nFET or pFET.

A capacitance 1122 might have a first electrode connected to the control gate of the second nFET 1116 and a second electrode connected to a fifth voltage node 1124. The fifth voltage node 1124 might be configured to receive a reference potential, such as 0V, Vss, or ground. The capacitance 1122 might be a capacitor, or might generally include one or more active or passive circuit elements configured to present a level of capacitance (e.g., a predetermined level of capacitance) in excess of conductive lines between the switch 1120 and the control gate of the second nFET 1116.

In operation, the first nFET 1108 might develop a voltage level on its control gate configured to pass the current level of the current source 1106. With the switch 1120 closed (e.g., a FET activated), this voltage level at the control gate of the first nFET 1108 can be sampled and stored on the capacitance 1122, and might further cause a current level through the second nFET 1116 proportional to (e.g., equal to) the current level of the current source 1106. By opening the switch 1120 (e.g., a FET deactivated), the sampled voltage level configured to pass the current level passing through the first nFET 1108 might be retained on the control gate of the second nFET 1116 and might continue to cause this same current level to pass through the second nFET 1116 even if current ceases to flow through the current source 1106 or through the first nFET 1108. In this manner, a current level through the first nFET 1108 could be sampled and supplied to an input of a transimpedance amplifier to produce an output voltage level that is representative of the sampled current level, and thus representative of a multiplication partial product of the sensing operation on a block of memory cells as discussed with reference to FIG. 5.

FIG. 11B is a block schematic of a current mirror 1100B using pFETs that could be used with embodiments. The current mirror 1100B might include a first voltage node 1102 configured to receive a first voltage level and a second voltage node 1104 configured to receive a second voltage level lower than the first voltage level. A current source 1106 connected between the first voltage node 1102 and the second voltage node 1104 might represent the current flow I_{SRC} from the block of memory cells being sensed or the current flow I_{REG} being absorbed to VBASE from the TIA 720, e.g., sinked from the TIA 720. A first pFET 1110 might be connected between the current source 1106 and the first voltage node 1102. The first pFET 1110 might be a diode-connected transistor with its drain connected to its control gate. Although depicted in FIG. 11B as a diode-connected pFET, the first pFET 1110 might simply represent a transistor passing a current level to be sampled, whether diode-connected or not.

The current mirror 1100B might further include a third voltage node 1112 configured to receive a third voltage level and a fourth voltage node 1114 configured to receive a fourth voltage level lower than the third voltage level. The third voltage level might be a same voltage level as the first voltage level, and the fourth voltage level might be a same voltage level as the second voltage level. A second pFET 1118 might be connected between the third voltage node 1112 and the fourth voltage node 1114. The second pFET 1118 might have the same size, e.g., a same width and length, as the first pFET 1110. A control gate of the second pFET 1118 might be selectively connected to the control gate of the first pFET 1110 through a switch 1120. The switch 1120 might be a FET, such as an nFET or pFET.

A capacitance 1122 might have a first electrode connected to the control gate of the second pFET 1118 and a second electrode connected to a fifth voltage node 1124. The fifth voltage node 1124 might be configured to receive a reference potential, such as 0V, Vss, or ground. The capacitance 1122 might be a capacitor, or might generally include one or more active or passive circuit elements configured to present a level of capacitance (e.g., a predetermined level of capacitance) in excess of conductive lines between the switch 1120 and the control gate of the second pFET 1118.

In operation, the first pFET 1110 might develop a voltage level on its control gate configured to pass the current level of the current source 1106. With the switch 1120 closed, this voltage level can be sampled and stored on the capacitance 1122, and might further cause a current level through the second pFET 1118 proportional to (e.g., equal to) the current level of the current source 1106. By opening the switch 1120, the sampled voltage level configured to pass the current level passing through the first pFET 1110 might be retained on the control gate of the second pFET 1118 and might continue to cause this same current level to pass through the second pFET 1118 even if current ceases to flow through the current source 1106 or through the first pFET 1110. In this manner, a current level through the first pFET 1110 could be sampled and supplied to an input of a transimpedance amplifier to produce an output voltage level that is representative of the sampled current level, and thus representative of a multiplication partial product of the sensing operation on a block of memory cells as discussed with reference to FIG. 5.

FIG. 11C is a block schematic of a current mirror 1100C using a mixture of nFETs and pFETs that could be used with embodiments for sampling the current level through an nFET and mirroring that current level on a pFET. The current mirror 1100C might include a first voltage node 1102 configured to receive a first voltage level and a second voltage node 1104 configured to receive a second voltage level lower than the first voltage level. A current source 1106 connected between the first voltage node 1102 and the second voltage node 1104 might represent the current flow I_{SRC} from the block of memory cells being sensed (e.g., the first current level or the second current level), or the current flow I_{REG} (e.g., I_{REG(ve+)} or I_{REG(ve-)}) being absorbed to VBASE from the TIA 720, e.g., sinked from the TIA 720. A first nFET 1108 might be connected between the current source 1106 and the second voltage node 1104. The first nFET 1108 might be a diode-connected transistor with its drain connected to its control gate. Although depicted in FIG. 11C as a diode-connected nFET, the first nFET 1108 might simply represent a transistor passing a current level to be sampled, whether diode-connected or not.

The current mirror 1100C might further include a third voltage node 1112 configured to receive a third voltage level and a fourth voltage node 1114 configured to receive a fourth voltage level lower than the third voltage level. The third voltage level might be a same voltage level as the first voltage level, and the fourth voltage level might be a same voltage level as the second voltage level. A second nFET 1116 might be connected between the third voltage node 1112 and the fourth voltage node 1114. The second nFET 1116 might have the same size, e.g., a same width and length, as the first nFET 1108. Alternatively, the second nFET 1116 might have a different (e.g., smaller) size than the first nFET 1108. A first pFET 1126 might be connected between the second nFET 1116 and the third voltage node 1112. The first pFET 1126 might be a diode-connected transistor with its drain connected to its control gate. The first pFET 1126 might have a same size as the second nFET 1116.

The current mirror 1100C might further include a fifth voltage node 1130 configured to receive a fifth voltage level and a sixth voltage node 1132 configured to receive a sixth voltage level lower than the fifth voltage level. The fifth voltage level might be a same voltage level as the first voltage level, and the sixth voltage level might be a same voltage level as the second voltage level. A second pFET 1134 might be connected between the fifth voltage node 1130 and the sixth voltage node 1132. The second pFET 1134 might have the same size as the first nFET 1108. A control gate of the second pFET 1134 might be selectively connected to the control gate of the first pFET 1126 through a switch 1120. The switch 1120 might be a FET, such as an nFET or pFET.

A capacitance 1122 might have a first electrode connected to the control gate of the second pFET 1134 and a second electrode connected to a seventh voltage node 1124. The seventh voltage node 1124 might be configured to receive a reference potential, such as 0V, Vss, or ground. The capacitance 1122 might be a capacitor, or might generally include one or more active or passive circuit elements configured to present a level of capacitance (e.g., a predetermined level of capacitance) in excess of conductive lines between the switch 1120 and the control gate of the second pFET 1134.

In operation, the first nFET 1108 might develop a voltage level on its control gate configured to pass the current level of the current source 1106. Receiving the same voltage level on its control gate, the second nFET 1116 might be expected to pass a current level proportional (e.g., depending upon the ratio of sizes) to the current level passed through the first nFET 1108. The diode-connected first pFET 1126 might develop a voltage level on its control gate to pass the same current level as the second nFET 1116. With the switch 1120 closed (e.g., a FET activated), this voltage level at the control gate of the first pFET 1126 can be sampled and stored on the capacitance 1122, and might further cause a current level through the second pFET 1134 proportional to (e.g., equal to) the current level passed through the first nFET 1108. By opening the switch 1120 (e.g., a FET deactivated), the sampled voltage level configured to mirror the current level passing through the first nFET 1108 might be retained on the control gate of the second pFET 1134 and might continue to cause this same current level to pass through the second pFET 1134 even if current ceases to flow through the current source 1106 or through the first nFET 1108. In this manner, a current level through the first nFET 1108 could be sampled and supplied to an input of a transimpedance amplifier to produce an output voltage level that is representative of the sampled current level, and thus representative of a multiplication partial product of the sensing operation on a block of memory cells as discussed with reference to FIG. 5.

FIG. 11D is a block schematic of a current mirror 1100D using a mixture of nFETs and pFETs that could be used with embodiments for sampling the current level through a pFET and mirroring that current level on an nFET. The current mirror 1100D might include a first voltage node 1102 configured to receive a first voltage level and a second voltage node 1104 configured to receive a second voltage level lower than the first voltage level. A current source 1106 connected between the first voltage node 1102 and the second voltage node 1104 might represent the current flow I_{SRC} from the block of memory cells being sensed (e.g., the first current level or the second current level), or the current flow I_{REG} (e.g., I_{REG(ve+)} or I_{REG(ve-)}) being absorbed to VBASE from the TIA 720, e.g., sinked from the TIA 720. A first pFET 1110 might be connected between the current source 1106 and the second voltage node 1104. The first pFET 1110 might be a diode-connected transistor with its drain connected to its control gate. Although depicted in FIG. 11D as a diode-connected nFET, the first pFET 1110 might simply represent a transistor passing a current level to be sampled, whether diode-connected or not.

The current mirror 1100D might further include a third voltage node 1112 configured to receive a third voltage level and a fourth voltage node 1114 configured to receive a fourth voltage level lower than the third voltage level. The third voltage level might be a same voltage level as the first voltage level, and the fourth voltage level might be a same voltage level as the second voltage level. A second pFET 1118 might be connected between the third voltage node 1112 and the fourth voltage node 1114. The second pFET 1118 might have the same size, e.g., a same width and length, as the first pFET 1110. Alternatively, the second pFET 1118 might have a different (e.g., smaller) size than the first pFET 1110. A first nFET 1128 might be connected between the second pFET 1118 and the third voltage node 1112. The first nFET 1128 might be a diode-connected transistor with its drain connected to its control gate. The first nFET 1128 might have a same size as the second pFET 1118.

The current mirror 1100D might further include a fifth voltage node 1130 configured to receive a fifth voltage level and a sixth voltage node 1132 configured to receive a sixth voltage level lower than the fifth voltage level. The fifth voltage level might be a same voltage level as the first voltage level, and the sixth voltage level might be a same voltage level as the second voltage level. A second nFET 1136 might be connected between the fifth voltage node 1130 and the sixth voltage node 1132. The second nFET 1136 might have the same size as the first pFET 1110. A control gate of the second nFET 1136 might be selectively connected to the control gate of the first nFET 1128 through a switch 1120. The switch 1120 might be a FET, such as an nFET or pFET.

A capacitance 1122 might have a first electrode connected to the control gate of the second nFET 1136 and a second electrode connected to a seventh voltage node 1124. The seventh voltage node 1124 might be configured to receive a reference potential, such as 0V, Vss, or ground. The capacitance 1122 might be a capacitor, or might generally include one or more active or passive circuit elements configured to present a level of capacitance (e.g., a predetermined level of capacitance) in excess of conductive lines between the switch 1120 and the control gate of the second nFET 1136.

In operation, the first pFET 1110 might develop a voltage level on its control gate configured to pass the current level of the current source 1106. Receiving the same voltage level on its control gate, the second pFET 1118 might be expected to pass a current level proportional (e.g., depending upon the ratio of sizes) to the current level passed through the first pFET 1110. The diode-connected first nFET 1128 might develop a voltage level on its control gate to pass the same current level as the second pFET 1118. With the switch 1120 closed (e.g., a FET activated), this voltage level at the control gate of the first nFET 1128 can be sampled and stored on the capacitance 1122, and might further cause a current level through the second nFET 1136 proportional to (e.g., equal to) the current level passed through the first pFET 1110. By opening the switch 1120 (e.g., a FET deactivated), the sampled voltage level configured to mirror the current level passing through the first pFET 1110 might be retained on the control gate of the second nFET 1136 and might continue to cause this same current level to pass through the second nFET 1136 even if current ceases to flow through the current source 1106 or through the first pFET 1110. In this manner, a current level through the first pFET 1110 could be sampled and supplied to an input of a transimpedance amplifier to produce an output voltage level that is representative of the sampled current level, and thus representative of a multiplication partial product of the sensing operation on a block of memory cells as discussed with reference to FIG. 5.

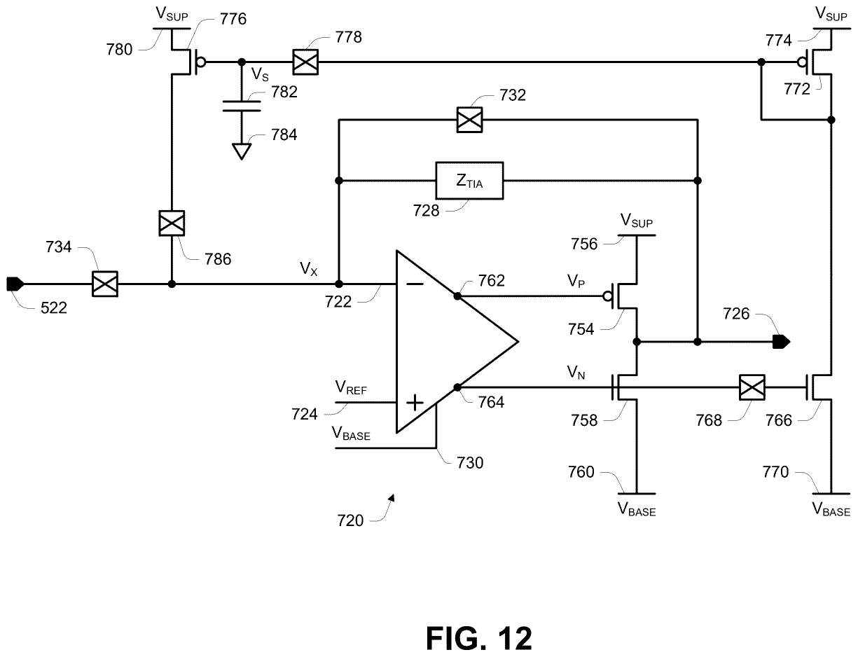

FIG. 12 is a block schematic of a TIA 720 in accordance with an embodiment. In FIG. 12, the TIA 720 might have a first input 722, a second input 724, an output 726, and an impedance (Z_{TIA}) 728 connected between its first input 722 and its output 726. The first input 722 might be an inverted input, and the second input 724 might be a non-inverted input. The second input 724 might be configured to receive a voltage level V_{REF}, e.g., a reference voltage level. The TIA 720 might further include a voltage node 730 configured to receive a voltage level VBASE, a base voltage level. The impedance 728 might represent a resistor, and might generally include one or more active or passive circuit elements configured to present a level of resistance (e.g., a predetermined level of resistance) to current flow from the first input 722 to the output 726, e.g., in excess of conductive lines between the input 722 and the output 726. In general, a transimpedance amplifier is configured as an operational amplifier (e.g., op-amp) with an impedance connected between its first input and its output. Although not depicted, a capacitance (e.g., a capacitor) might further be connected between the first input 722 and the output 726 in parallel with the impedance 728.

Unconventionally, for various embodiments, the TIA 720 might further include a switch 732 connected between the first input 722 and the output 726 in parallel with the impedance 728, e.g., to permit bypassing the impedance 728. For various embodiments, the first input 722 thus might be selectively directly connected to the output 726, such that current flow preferentially flows through the switch 732 rather than the impedance 728. The switch 732 might represent a FET, which might be an nFET or a pFET.

The first input 722 of the TIA 720 might be selectively connected to the node 522 and thus to the common source 216 through a switch 734 in order to receive a current from the node 522. The switch 734 might represent a FET, which might be an nFET or a pFET. Although the structure and design of the TIA 720, aside from the switch 732, could take a variety of forms recognized in the art, each will generally include a voltage node 756 to inject current into the output 726 and a voltage node 760 to absorb current from the output 726. The voltage node 756 might be configured to receive a voltage level V_{SUP}, e.g., a supply voltage level, and the voltage node 760 might be configured to receive the voltage level VBASE. The voltage level V_{SUP} might be the supply voltage Vcc or other positive externally-supplied or internally-generated voltage level that is higher than the voltage level VBASE. The voltage level V_{SUP} might represent a highest value of a voltage level on the output 726 and the voltage level VBASE might represent a lowest value of a voltage level on the output 726.

The voltage node 756 might be selectively connected to the output 726 through a pFET 754 having its control gate connected to a node 762 of the TIA 720. The node 762 might represent a control node configured to control current flow from the voltage node 756 to the output 726 to maintain the voltage level V_{X} at the first input 722 equal to the voltage level V_{REF} at the second input 724.

The voltage node 760 might be selectively connected to the output 726 through an nFET 758 having its control gate connected to a node 764 of the TIA 720. The node 764 might represent a control node configured to control current flow from the output 726 to the voltage node 760 to maintain the voltage level V_{X} at the first input 722 equal to the voltage level V_{REF} at the second input 724.

The control gate of the nFET 758 might be selectively connected to an nFET 766 through a switch 768. The switch 768 might be a FET, such as an nFET or pFET. A first source/drain (e.g., source) of the nFET 766 might be connected to a voltage node 770 configured to receive the voltage level VBASE. A second source/drain (e.g., drain) of the nFET 766 might be connected to a first source/drain (e.g., drain) of a pFET 772. A second source/drain (e.g., source) of the pFET 772 might be connected to a voltage node 774 configured to receive the voltage level V_{SUP}. The pFET 772 might be a diode-connected transistor, having its control gate connected to its drain.

The control gate of the pFET 772 might be selectively connected to the control gate of a pFET 776 through a switch 778. The switch 778 might be a FET, such as an nFET or pFET. A capacitance 782 might have a first electrode connected to the control gate of the pFET 776 and a second electrode connected to a voltage node 784. The voltage node 784 might be configured to receive a reference potential, such as 0V, Vss, or ground. The capacitance 782 might be a capacitor, or might generally include one or more active or passive circuit elements configured to present a level of capacitance (e.g., a predetermined level of capacitance) in excess of conductive lines between the switch 778 and the control gate of the pFET 776. A first source/drain (e.g., drain) of the pFET 776 might be selectively connected to the first input 722 of the TIA 720 through a switch 786. The switch 786 might be a FET, such as an nFET or pFET. A second source/drain (e.g., source) of the pFET 776 might be connected to a voltage node 780 configured to receive the voltage level V_{SUP}.

The nFET 766 and the pFET 772 might have the same size, e.g., a same width and length. The nFET 758 and the pFET 776 might have the same size, e.g., a same width and length. The nFET 766 might have a same or different size than the nFET 758. However, to reduce power consumption, the nFET 766 might be sized to be smaller than the nFET 758, e.g., the nFET 766 might have a smaller width and/or length than the nFET 758 to cause its conductance to be lower in response to the same control gate voltage level.

In operation, the switch 786 might be open (e.g., a FET deactivated) and the switch 734 might be closed (e.g., a FET activated) during a sensing operation on a block of memory cells in order to pass the current from the common source to the first input 722 of the TIA 720. The switch 732 might be closed to bypass the impedance 728. In seeking to maintain the voltage level Vx at the first input 722 equal to the reference voltage level V_{REF} at the second input 724, the TIA 720 might be expected to sink an amount of current to the voltage node 760 equal to the amount of current sourced to the first input 722 from the node 522. To attain a steady-state current flow through the nFET 758, a control signal from the node 764 might settle to a voltage level configured to produce the desired level of conductance of the nFET 758. Concurrently, a control signal from the node 762 might settle to a voltage level configured to deactivate the pFET 754.

The switch 768 might then be closed. This might occur after reaching a steady state of current flow through the nFET 758. As a result, the diode-connected pFET 772 might develop a voltage level on its control gate configured to pass the current flowing through the nFET 766 in response to the control gate voltage level of the nFET 758. With the switch 778 closed, this voltage level can be sampled and stored on the capacitance 782. As this voltage level is configured to produce a current level through the pFET 772 equal to the current level through the nFET 766, this voltage level might further be configured to produce a current level through the pFET 776 equal to the current level through the nFET 758 in response to the ratio of the size of the pFET 776 to the size of the pFET 772 being equal to the ratio of the size of the nFET 758 to the size of the nFET 766. Note that if the ratios are not equal, the current level through the pFET 776 might be expected to be proportional to the current level through the nFET 758, and thus still representative of the current level received from the node 522. By opening the switch 778, the sampled voltage level might be retained on the control gate of the pFET 776. The switch 734 might then be opened to isolate the TIA 720 from the node 522, the switch 732 might be opened, and the switch 786 might be closed to provide a current level to the first input 722 configured to be equal to the sampled current level while current flow from the first input 722 to the output 726 is through the impedance 728.

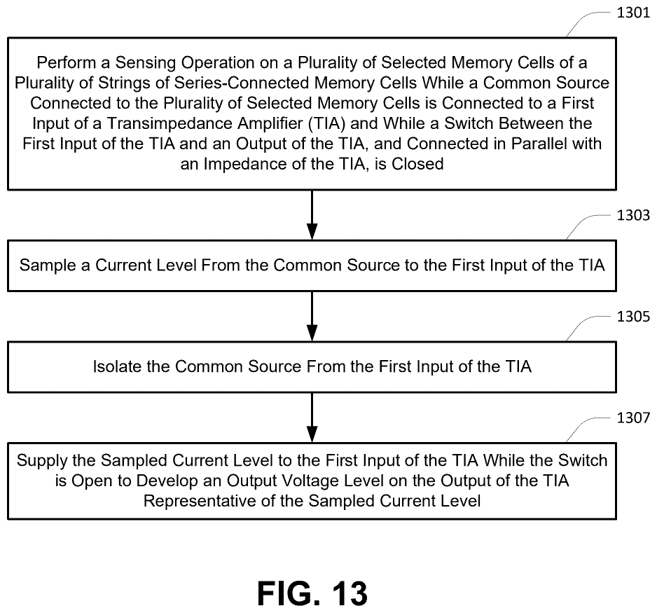

FIG. 13 is a flowchart of a method of operating a memory in accordance with an embodiment. The method might represent actions associated with a sensing operation. The method might be in the form of computer-readable instructions, e.g., stored to the instruction registers 128. Such computer-readable instructions might be executed by a controller, e.g., the control logic 116, to cause the relevant components of the memory to perform the method.

At 1301, a sensing operation might be performed on a plurality of selected memory cells of a plurality of strings of series-connected memory cells while a common source connected to the plurality of selected memory cells is connected to a first input of a transimpedance amplifier (TIA) and while a switch between the first input of the TIA and an output of the TIA, and connected in parallel with an impedance of the TIA, is closed. The selected memory cells might be memory cells of the block of memory cells 250 of FIG. 5 that are connected to one of the access line 202₀-202₃ and selectively connected to one or more of the data lines 204₀-204₇ in response to control signals received on one or more of the select lines 215₀-215₂. The node 522 connected to the common source 216 might be connected to the first input 722 of a TIA 720, and the switch 732 might be closed.

At 1303, a current level from the common source to the first input of the TIA might be sampled. For example, a current level I_{REG} being sinked from the TIA 720 of FIG. 8A might be sampled.

At 1305, the common source might be isolated from the first input of the TIA. For example, the switch 734 might be opened as depicted in FIG. 9A.

At 1307, the sampled current level might be supplied to the first input of the TIA while the switch is open to develop an output voltage level on the output of the TIA representative of the sampled current level. For example, the switch 732 might be open while the sampled current level I_{REG} is supplied to the first input of the TIA 720 as depicted in FIGS. 9A and/or 10A.

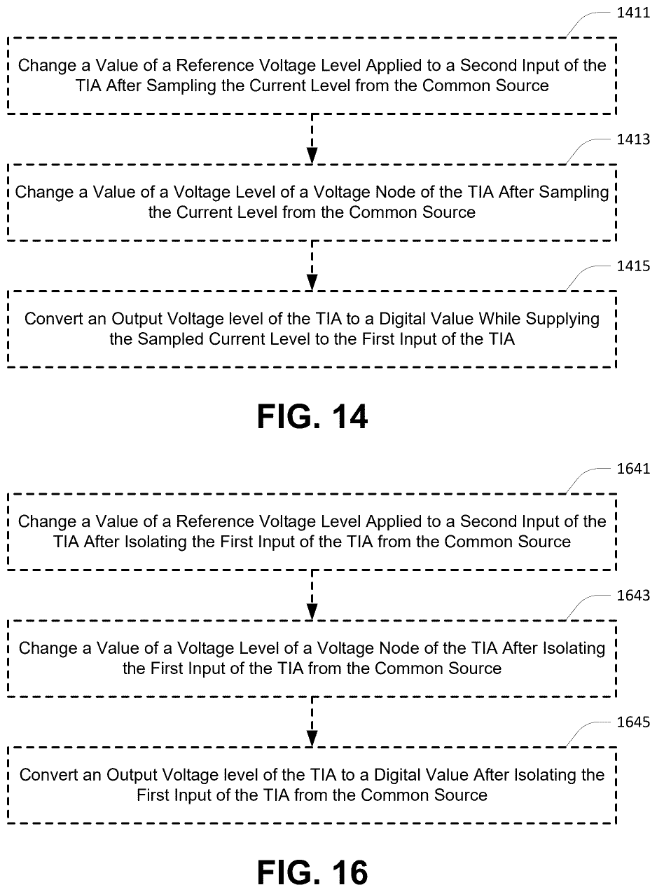

FIG. 14 is a flowchart of a method of operating a memory in accordance with a further embodiment. The method might represent optional actions associated with a sensing operation such as described with reference to FIG. 13. The method might be in the form of computer-readable instructions, e.g., stored to the instruction registers 128. Such computer-readable instructions might be executed by a controller, e.g., the control logic 116, to cause the relevant components of the memory to perform the method.

Optionally, at 1411, a value of a reference voltage level applied to a second input of the TIA might be changed after sampling the current level from the common source. For example, a value of the voltage level V_{REF} applied to the second input 724 of the TIA 720 of FIG. 10A might be changed in response to preferences of the neural network, e.g., to move the intercept of the plot of FIG. 10B to a zero point.

Optionally, at 1413, a value of a voltage level of a voltage node (e.g., a lowest voltage node) of the TIA might be changed after sampling the current level from the common source. For example, a value of the voltage level VBASE might be changed in response to preferences of the neural network, e.g., to provide for a negative voltage response of a Leaky ReLU.

Optionally, at 1415, an output voltage level of the TIA might be converted to a digital value while supplying the sampled current level to the first input of the TIA. For example, the output 726 of the TIA 720 of FIG. 7 might be connected to the input 742 of an ADC 744 to produce a digital value on the outputs 752 of the ADC 744.

While the acts 1411-1415 are depicted to be sequential, one or more of these acts might be performed concurrently. In addition, various embodiments alternatively might perform any one or two of the three acts. For example, the output voltage level might be converted to a digital value without changing either the reference voltage level or the value of the voltage level of the voltage node, or the output voltage level might be converted to a digital value while changing only one of the value of the reference voltage level or the value of the voltage level of the voltage node.

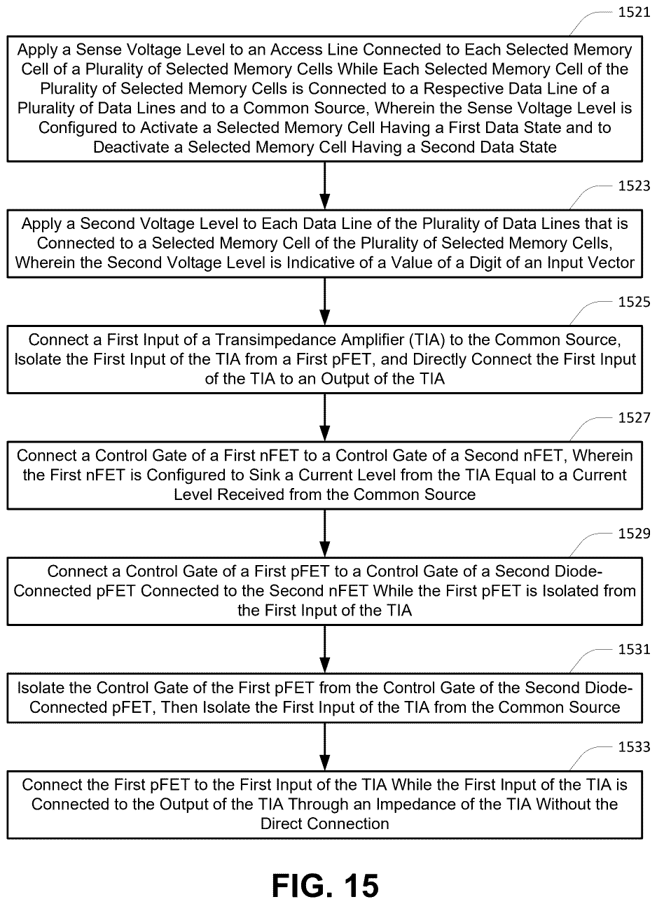

FIG. 15 is a flowchart of a method of operating a memory in accordance with an embodiment. The method might represent actions associated with a sensing operation. The method might be in the form of computer-readable instructions, e.g., stored to the instruction registers 128. Such computer-readable instructions might be executed by a controller, e.g., the control logic 116, to cause the relevant components of the memory to perform the method.

At 1521, a sense voltage level might be applied to an access line connected to each selected memory cell of a plurality of selected memory cells while each selected memory cell of the plurality of selected memory cells is connected to a respective data line of a plurality of data lines and to a common source, wherein the sense voltage level is configured to activate a selected memory cell having a first data state and to deactivate a selected memory cell having a second data state. For example, with reference to FIG. 5, one of the access line 202₀-202₃ might receive the sense voltage level while one or more of the select lines 215₀-215₂ receives a control signal configured to connect its corresponding NAND strings 206 to one or more of the data lines 204₀-204₇, while the select line 214 receives a control signal to connect the NAND strings 206 to the common source 216, and while remaining access lines 202 receive pass voltage levels configured to activate all memory cells connected to those access lines 202.

At 1523, a second voltage level might be applied to each data line of the plurality of data lines that is connected to a selected memory cell of the plurality of selected memory cells, wherein the second voltage level is indicative of a value of a digit of a multiplier vector (e.g., an input vector). For example, where the digit of the multiplier vector has a first input data value (e.g., 1), the second voltage level might be a positive voltage level, and where the digit of the multiplier vector has a second input data value (e.g., 0), different than the first input data value, the second voltage level might be a reference potential or the voltage level of the common source 216. This might generate a current level from the data lines to the common source during the sensing operation, which might range from no current flow to some positive current flow.

At 1525, a first input of a transimpedance amplifier (TIA) might be connected to the common source, the first input of the TIA might be isolated from a first pFET, and the first input of the TIA might be directly connected to an output of the TIA. For example, with reference to FIG. 12, the first input 722 of the TIA 720 might be connected to the node 522 (e.g., connected to the common source 216 in FIG. 5) by closing the switch 734, the first input 722 of the TIA 720 might be isolated from the pFET 776 by opening the switch 786, and the first input 722 of the TIA 720 might be directly connected to the output 726 of the TIA 720 by closing the switch 732.

At 1527, a control gate of a first nFET might be connected to a control gate of a second nFET, wherein the first nFET is configured to sink a current level from the TIA equal to a current level received from the common source. For example, with reference to FIG. 12, the nFET 758 might be connected to the nFET 766 by closing the switch 768.

At 1529, a control gate of a first pFET might be connected to a control gate of a second diode-connected pFET connected to the second nFET while the first pFET is isolated from the first input of the TIA. For example, with reference to FIG. 12, the control gate of the pFET 776 might be connected to the control gate of the diode-connected pFET 772, which is connected to the nFET 766, by closing the switch 778 while the switch 786 is open.

At 1531, the control gate of the first pFET might be isolated from the control gate of the second diode-connected pFET, then the first input of the TIA might be isolated from the common source. For example, with reference to FIG. 12, the control gate of the pFET 776 might be isolated from the control gate of the pFET 772 by opening the switch 778, then the first input 722 of the TIA 720 might be isolated from the common source (e.g., the node 522) by opening the switch 734.

At 1533, the first pFET might be connected to the first input of the TIA while the first input of the TIA is connected to the output of the TIA through an impedance of the TIA without the direct connection. For example, with reference to FIG. 12, the pFET 776 might be connected to the first input 722 of the TIA 720 by closing the switch 786 while the first input 722 of the TIA 720 is connected to the output 726 of the TIA 720 through the impedance 728 by opening the switch 732. The voltage level retained by the capacitance 782 might facilitate producing a current level through the pFET 776 proportional to (e.g., equal to) a current level being sinked from the TIA 720 through the nFET 758.

FIG. 16 is a flowchart of a method of operating a memory in accordance with a further embodiment. The method might represent optional actions associated with a sensing operation such as described with reference to FIG. 15. The method might be in the form of computer-readable instructions, e.g., stored to the instruction registers 128. Such computer-readable instructions might be executed by a controller, e.g., the control logic 116, to cause the relevant components of the memory to perform the method.

Optionally, at 1641, a value of a reference voltage level applied to a second input of the TIA might be changed after isolating the first input of the TIA from the common source. For example, a value of the voltage level V_{REF} applied to the second input 724 of the TIA 720 of FIG. 12 might be changed in response to preferences of the neural network, e.g., to move the intercept of the plot of FIG. 10B to a zero point.

Optionally, at 1643, a value of a voltage level of a voltage node of the TIA might be changed after isolating the first input of the TIA from the common source. For example, the value of the voltage level VBASE applied to the voltage node 760, and to voltage nodes 730 and 770, might be changed in response to preferences of the neural network, e.g., to provide for a negative voltage response of a Leaky ReLU.

Optionally, at 1645, an output voltage level of the TIA might be converted to a digital value after isolating the first input of the TIA from the common source. For example, the output 726 of the TIA 720 of FIG. 12 might be connected to the input 742 of an ADC 744 of FIG. 7 to produce a digital value on the outputs 752 of the ADC 744.

While the acts 1641-1645 are depicted to be sequential, one or more of these acts might be performed concurrently. In addition, various embodiments alternatively might perform any one or two of the three acts. For example, the output voltage level might be converted to a digital value without changing either the reference voltage level or the value of the voltage level of the voltage node, or the output voltage level might be converted to a digital value while changing only one of the reference voltage level or the value of the voltage level of the voltage node.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A memory, comprising:
an array of memory cells comprising a plurality of strings of series-connected memory cells;
a common source selectively connected to each string of series-connected memory cells of the plurality of strings of series-connected memory cells;
a plurality of data lines, wherein each data line of the plurality of data lines is selectively connected to a respective string of series-connected memory cells of the plurality of strings of series-connected memory cells;
a transimpedance amplifier (TIA) having a first input selectively connected to the common source, a second input configured to receive a reference voltage level, an output, an impedance connected between the first input and the output, and a switch connected between the first input and the output in parallel with the impedance; and
a controller for access of the array of memory cells, wherein the controller is configured to cause the memory to:
perform a sensing operation on a plurality of selected memory cells of the plurality of strings of series-connected memory cells while the common source is connected to the first input of the TIA and while the switch is closed;
sample a current level from the common source to the first input of the TIA;
isolate the common source from the TIA; and
supply the sampled current level to the first input of the TIA while the switch is open to develop an output voltage level on the output representative of the sampled current level.

2. The memory of claim 1, wherein the controller is further configured to cause the memory to convert an output voltage level of the TIA to a digital value while supplying the sampled current level to the first input of the TIA.

3. The memory of claim 1, wherein the controller being configured to cause the memory to perform the sensing operation on the plurality of selected memory cells comprises the controller being configured to cause the memory to:
apply a sense voltage level to an access line connected to each selected memory cell of the plurality of selected memory cells while each selected memory cell of the plurality of selected memory cells is connected to its respective data line and to the common source, wherein the sense voltage level is configured to activate a selected memory cell having a first data state and to deactivate a selected memory cell having a second data state;
apply a second voltage level to each data line of the plurality of data lines that is connected to a selected memory cell of the plurality of selected memory cells, wherein the second voltage level is indicative of a value of a digit of an input vector to the memory.

4. The memory of claim 1, wherein more than one selected memory cell is connected to each data line of the plurality of data lines that is connected to a selected memory cell of the plurality of selected memory cells during the sensing operation.

5. The memory of claim 1, wherein the controller being configured to cause the memory to sample the current level from the common source to the first input of the TIA comprises the controller being configured to cause the memory to sample a current level being sinked from the output of the TIA.

6. The memory of claim 1, wherein the TIA further comprises:
a first n-type field-effect transistor (nFET) having a control gate connected to a control node of the TIA, having a first source/drain connected to a first voltage node configured to receive a first voltage level, and having a second source/drain connected to the output;
a second nFET having a control gate selectively connected to the control gate of the first nFET through a second switch, having a first source/drain connected to a second voltage node configured to receive the first voltage level, and having a second source/drain;
a first p-type field-effect transistor (pFET) having a control gate, having a first source/drain connected to a third voltage node configured to receive a second voltage level higher than the first voltage level, and having a second source/drain selectively connected to the first input of the TIA through a third switch; and
a second pFET having a first source/drain connected to a fourth voltage node configured to receive the second voltage level, having a second source/drain connected to the second source/drain of the second nFET, and having a control gate connected to its second source/drain and selectively connected to the control gate of the first pFET through a fourth switch; and
a capacitance having a first electrode connected to the control gate of the second pFET, and a second electrode connected to a fifth voltage node configured to receive a reference potential.

7. The memory of claim 6, wherein the controller being configured to cause the memory to sample the current level from the common source to the first input of the TIA comprises the controller being configured to cause the memory to:
connect the control gate of the first nFET to the control gate of the second nFET;
connect the control gate of the first pFET to the control gate of the second pFET while the first pFET is isolated from the first input of the TIA;
isolate the control gate of the first pFET from the control gate of the second pFET, then isolate the first input of the TIA from the common source; and
connect the first pFET to the first input of the TIA.

8. The memory of claim 1, wherein the controller is further configured to cause the memory to change a value of the first voltage level after sampling the current level from the common source to the first input of the TIA.

9. The memory of claim 8, wherein changing the value of the first voltage level comprises changing the value of the first voltage level to a negative voltage level.

10. A memory, comprising:
an array of memory cells comprising a plurality of strings of series-connected memory cells;
a common source selectively connected to each string of series-connected memory cells of the plurality of strings of series-connected memory cells;
a plurality of data lines, wherein each data line of the plurality of data lines is selectively connected to a respective string of series-connected memory cells of the plurality of strings of series-connected memory cells; and
a transimpedance amplifier (TIA) having a first input selectively connected to the common source, a second input configured to receive a reference voltage level, an output, and an impedance connected between the first input and the output, wherein the first input is further selectively directly connected to the output in parallel with the impedance.

11. The memory of claim 10, wherein the TIA further comprises:
a first n-type field-effect transistor (nFET) having a first source/drain connected to a first voltage node configured to receive a first voltage level and having a second source/drain connected to the output;
a second nFET having a control gate selectively connected to a control gate of the first nFET, having a first source/drain connected to a second voltage node configured to receive the first voltage level, and having a second source/drain;
a first pFET having a first source/drain connected to a third voltage node configured to receive a second voltage level higher than the first voltage level, having a second source/drain connected to the second source/drain of the second nFET, and having a control gate connected to its second source/drain;
a second pFET having a first source/drain connected to a fourth voltage node configured to receive the second voltage level, having a second source/drain selectively connected to the first input of the TIA, and having a control gate selectively connected to the control gate of the first pFET; and
a capacitance having a first electrode connected to the control gate of the second pFET, and a second electrode connected to a fifth voltage node configured to receive a reference potential.

12. The memory of claim 11, wherein the first voltage level is lower than the reference voltage level.

13. The memory of claim 12, wherein the second voltage level is higher than the reference voltage level.

14. The memory of claim 11, wherein the TIA further comprises:
a third pFET having a first source/drain connected to a sixth voltage node configured to receive the second voltage level, and having a second source/drain connected to the output of the TIA.

15. A memory, comprising:
an array of memory cells comprising a plurality of strings of series-connected memory cells;
a common source selectively connected to each string of series-connected memory cells of the plurality of strings of series-connected memory cells;
a plurality of data lines, wherein each data line of the plurality of data lines is selectively connected to a respective string of series-connected memory cells of the plurality of strings of series-connected memory cells;
a transimpedance amplifier (TIA) comprising:
a first input selectively connected to the common source;
a second input configured to receive a reference voltage level;
an output;
an impedance connected between the first input and the output, wherein the first input is further selectively directly connected to the output bypassing the impedance;
a first n-type field-effect transistor (nFET) having a first source/drain connected to a first voltage node configured to receive a first voltage level and having a second source/drain connected to the output;
a second nFET having a control gate selectively connected to a control gate of the first nFET, having a first source/drain connected to a second voltage node configured to receive the first voltage level, and having a second source/drain;
a first p-type field-effect transistor (pFET) having a first source/drain connected to a third voltage node configured to receive a second voltage level higher than the first voltage level, having a second source/drain connected to the second source/drain of the second nFET, and having a control gate connected to its second source/drain;
a second pFET having a first source/drain connected to a fourth voltage node configured to receive the second voltage level, having a second source/drain selectively connected to the first input of the TIA, and having a control gate selectively connected to the control gate of the first pFET; and
a capacitance having a first electrode connected to the control gate of the second pFET, and a second electrode connected to a fifth voltage node configured to receive a reference potential; and
a controller for access of the array of memory cells, wherein the controller is configured to cause the memory to:
apply a sense voltage level to an access line connected to each selected memory cell of the plurality of selected memory cells while each selected memory cell of the plurality of selected memory cells is connected to its respective data line and to the common source, wherein the sense voltage level is configured to activate a selected memory cell having a first data state and to deactivate a selected memory cell having a second data state;
apply a third voltage level to each data line of the plurality of data lines that is connected to a selected memory cell of the plurality of selected memory cells, wherein the third voltage level is indicative of a value of a digit of an input vector to the memory;
connect the first input of the TIA to the common source, isolate the first input of the TIA from the second pFET, and directly connect the first input of the TIA to the output of the TIA;
connect the control gate of the first nFET to the control gate of the second nFET;
connect the control gate of the first pFET to the control gate of the second pFET while the second pFET is isolated from the first input of the TIA;
isolate the control gate of the first pFET from the control gate of the second pFET, then isolate the first input of the TIA from the common source; and
connect the second pFET to the first input of the TIA while the first input of the TIA is connected to the output of the TIA through the impedance without the direct connection.

16. The memory of claim 15, wherein the first voltage level is lower than the reference voltage level.

17. The memory of claim 16, wherein the first voltage level is the reference potential.

18. The memory of claim 16, wherein the second voltage level is higher than the reference voltage.

19. The memory of claim 15, wherein the controller is further configured to cause the memory to convert an output voltage level of the TIA to a digital value after isolating the first input of the TIA from the common source.

20. The memory of claim 15, wherein the controller is further configured to cause the memory to:
change a value of the reference voltage level after isolating the first input of the TIA from the common source;
change a value of the first voltage level after isolating the first input of the TIA from the common source; and
convert an output voltage level of the TIA to a digital value after changing the value of the reference voltage level and changing the value of the first voltage level.
